(19) United States
(12) Patent Application Publication
(10) Pub. No.: US 2009/0116675 A1
(43) Pub. Date: May 7, 2009

(54) MEMS DIAPHRAGM STRUCTURE AND METHOD FOR FORMING THE SAME

(76) Inventor: Yuichi Miyoshi, Niigata (JP)

Correspondence Address: MCDERMOTT WILL & EMERY LLP, 600 13TH STREET, NW, WASHINGTON, DC, 20005-3096, US

(21) Appl. No.: 12/092,762

(22) PCT Filed: Aug. 3, 2006
(86) PCT No.: PCT/JP2006/315379

§ 371 Date: May 6, 2008

(30) Foreign Application Priority Data
Dec. 14, 2005 (JP) 2005-360558

(51) Int. Cl. H04R 19/04; G01P 15/125; H01L 21/306

(52) U.S. Cl. 381/369; 73/514.32; 438/694; 257/E21.219

(57) ABSTRACT

A diaphragm (14) is formed using MEMS technology. The diaphragm (14) has a hinge structure, and at least one of a hinge upper corner portion and a hinge lower corner portion of the diaphragm (14) is rounded.

### TECHNICAL FIELD

The present invention relates to an acceleration sensor, a pressure sensor, or the like using MEMS (Micro Electro Mechanical Systems) technology. Specifically, the present invention relates to a structure of a diaphragm serving as a part detecting an acceleration change, a pressure change, or the like and then vibrating and to a method for forming the same.

### BACKGROUND ART

In recent years, advances have been made in a technical field called MEMS by making use of fine processing technology used in a field of fabricating LSI (large-scale integrated) circuits adopting a semiconductor such as silicon. By using the MEMS technology, various types of fine components such as an acceleration sensor and a pressure sensor have been proposed and produced on a commercial basis.

The acceleration sensor or the pressure sensor includes a diaphragm serving as a part detecting an acceleration change or a pressure change and then vibrating.

FIGS. 13A through 13E are cross-sectional views illustrating respective steps of a conventional method for forming a diaphragm structure.

First, as illustrated with FIG. 13A, a silicon substrate 201 is provided. Then, as illustrated with FIG. 13B, on an upper surface of the silicon substrate 201, a diaphragm 202a is formed. As the silicon substrate 201, a silicon substrate which is generally used in an LSI fabrication and whose top surface has the (100) plane direction is often used. As the diaphragm 202a, a thin film (single-layer film) such as a silicon oxide film, a silicon nitride film, or a polysilicon film formed by thermal oxidation or CVD (chemical vapor deposition), or a multi-layer film composed thereof is used. In the case of using the thermal oxidation or an LP (low pressure)-CVD, simultaneously with the formation of the diaphragm 202a on the upper surface of the silicon substrate 201, a diaphragm 202b is also formed on a reverse surface of the silicon substrate 201.

Next, as illustrated with FIG. 13C, a resist is applied on a reverse surface side of the silicon substrate 201. Then, the resist is patterned to form a resist pattern 203. Then, by using the resist pattern 203 as a mask, a predetermined portion of the diaphragm 202b is removed by etching to pattern the diaphragm 202b on the substrate reverse surface side, and then the resist pattern 203 is removed as shown in FIG. 13D.

Lastly, as illustrated with FIG. 13E, a predetermined portion of the silicon substrate 201 is removed by etching using the patterned diaphragm 202b on the substrate reverse surface side as a mask to form a through hole in the silicon substrate 201. As a result, the diaphragm 202a both ends of which are supported by the silicon substrate 201 and a center portion of which is in the air is formed on a substrate upper surface side. In the case of using an alkaline aqueous solution such as KOH to etch the silicon substrate 201, it is possible to anisotropically etch the silicon substrate 201 with the (111) plane direction left on an etched surface.

The diaphragm 202a formed in this way vibrates in response to the acceleration change or the pressure change. Therefore, using the diaphragm 202a as one electrode (or providing one electrode on the diaphragm 202a) and providing the other electrode to face the diaphragm 202a make it possible to detect vibration displacement of the diaphragm 202a as a capacitance change or a voltage change. That is, it is possible to form an acceleration sensor, a pressure sensor, or the like including the diaphragm 202a.

Now, according to the order of the acceleration change or the pressure change which is to be detected, it is necessary to appropriately control the amount of vibration (the amplitude) of the diaphragm. To control the amplitude, there are three methods as follows. A first method is “to vary a parameter such as the film type or the film thickness of the diaphragm itself to change the film softness”. However, in this method, the film type, the film thickness, or the like is often restricted by a diaphragm formation process, and thus it is difficult to freely vary the amplitude of the diaphragm. A second method is “to change the two-dimensional (XY) size of the diaphragm”. However, also in this method, since the chip size is restricted by a final product form, the amplitude of the diaphragm can not be freely varied. A third method is “to bend the diaphragm to provide the diaphragm with a hinge structure”. Since the third method can be used with less restriction by the diaphragm formation process or the chip size as in the above-mentioned two methods, the third method is thought to be effective.

The diaphragm having the above-mentioned hinge structure has been proposed in, for example, Patent Document 1 and Patent Document 2. As an example, a conventional diaphragm structure and a method for forming the same disclosed in Patent Document 1 will be described below.

FIGS. 14A through 14G are cross-sectional views illustrating respective steps of the method for forming the conventional diaphragm structure disclosed in Patent Document 1.

First, as illustrated with FIG. 14A, a silicon substrate 301 is provided. Then, as illustrated with FIG. 14B, on an upper surface of the silicon substrate 301, a silicon oxide film 302 is formed. Then, as illustrated with FIG. 14C, on the silicon oxide film 302, a resist is applied and patterned to form a resist pattern 303.

Then, as illustrated with FIG. 14D, postbaking is performed at a temperature of 120-140° C. to round edges (upper corner portions) of the resist pattern 303. Then, as illustrated with FIG. 14E, by using the resist pattern 303 as a mask, predetermined portions respectively of the silicon oxide film 302 and the silicon substrate 301 are removed by etching. Then, the resist pattern 303 is removed. It is to be noted that although there is no detailed description in Patent Document 1, it is illustrated that edges (upper corner portions) of the silicon oxide film 302 are rounded in the etching of FIG. 14E. That is, it is thought that during or after the etching illustrated with FIG. 14E, the edges (the upper corner portions) of the silicon oxide film 302 are rounded.

Then, as illustrated with FIG. 14F, on the patterned silicon oxide film 302 and on the upper surface of the silicon substrate 301, a diaphragm 304 is formed. Here, since the diaphragm 304 is formed to cover depressions and projections formed on the substrate upper surface by the patterned silicon oxide film 302, the diaphragm 304 has bends.

Then, as illustrated with FIG. 14G, a resist pattern (not shown) is formed on a reverse surface side of the silicon substrate 301, and then by using the resist pattern as a mask, a predetermined portion of the silicon substrate 301 is removed by etching from the reverse surface side to form a through hole. As a result, the diaphragm 304 having a hinge structure can be formed.

Patent Document 1: Specification of U.S. Pat. No. 6,168,906

### Patent Document 2: Specification of United States Patent Application Publication No. 2002/0118850

### DISCLOSURE OF INVENTION

### Problems to be Solved by the Invention

However, the diaphragm having the hinge structure formed according to the method illustrated with FIGS. 14A through 14G has corner portions bent at a right angle. Therefore, in the course of the diaphragm formation process or at the time of using the diaphragm as a sensor, stress concentration at the corners occurs. As a result, the problem arises that the diaphragm may be torn at the corners.

It is to be noted that in the diaphragm structure obtained by the conventional method illustrated with FIGS. 14A through 14G, hinge upper corner portions are apparently rounded. However, it is difficult to practically round the hinge upper corner portions as shown in FIG. 14G. This is because the way in which the hinge upper corner portions are rounded in the conventional art depends on the shape of the resist and the silicon oxide film which are etched during silicon etching of FIG. 14E, in other words, depends on the selectivity to the resist and the selectivity to the silicon oxide film during the silicon etching, and thus the way in which the hinge upper corner portions are rounded can not be controlled as intended.

In view of the problem mentioned above, an object of the present invention is to provide a diaphragm having a hinge structure in which the stress concentration on hinge corner portions is prevented to improve reliability of the diaphragm.

### Means for Solving the Problems

To achieve the object mentioned above, the inventor has conceived of the invention in which a structure in which hinge corner portions of a diaphragm are formed to have an obtuse angle or rounded is adopted, and in addition to this, steps for forming the structure are performed under control or a structure to reinforce the hinge corner portions is provided so that the stress concentration on the hinge corner portions is dispersed or so that the stress limit (the magnitude of stress at which a film begins to tear) is improved, thereby improving the resistance of the diaphragm against film breakage.

Specifically, a first diaphragm structure according to the present invention is a structure including a diaphragm formed using MEMS technology, wherein the diaphragm has a hinge structure, and at least one of a hinge upper corner portion and a hinge lower corner portion of the diaphragm is bent at an angle greater than 90°.

According to the first diaphragm structure of the present invention, at least one of the hinge upper corner portion and the hinge lower corner portion of the diaphragm is bent at an angle of greater than 90°. Therefore, the stress concentration on the hinge corner portion can be dispersed. As a result, the resistance of the diaphragm against film breakage can be improved.

It is to be noted that, in the present application, the hinge upper corner portion means “a position where the diaphragm is bent from a high level to a low level”, and the hinge lower corner portion means “a position where the diaphragm is bent from the low level to the high level”.

In the first diaphragm structure of the present invention, it is preferable that the diaphragm has a high-level-side flat portion, a low-level-side flat portion, and a connection portion connecting the high-level-side flat portion and the low-level-side flat portion, and the connection portion is provided in an oblique direction to the high-level-side flat portion and the low-level-side flat portion.

Thus, both the hinge upper corner portion and the hinge lower corner portion of the diaphragm can be formed to have an obtuse angle.

A second diaphragm structure of the present invention includes a diaphragm formed using MEMS technology, wherein the diaphragm has a hinge structure, and at least one of a hinge upper corner portion and a hinge lower corner portion of the diaphragm is rounded.

According to the second diaphragm structure of the present invention, at least one of the hinge upper corner portion and the hinge lower corner portion of the diaphragm is rounded. Therefore, the stress concentration on the hinge corner portion can be dispersed. As a result, the resistance of the diaphragm against film breakage can be improved.

In the second diaphragm structure of the present invention, the other portions of the diaphragm than the hinge upper corner portion and the hinge lower corner portion may also be rounded.

A third diaphragm structure of the present invention includes a diaphragm formed using MEMS technology, wherein the diaphragm has a hinge structure, and at least one of a hinge upper corner portion and a hinge lower corner portion of the diaphragm is greater in film thickness than the other portions of the diaphragm.

According to the third structure of the diaphragm of the present invention, at least one of the hinge upper corner portion and the hinge lower corner portion is greater in film thickness than the other portions (for example, the flat portions) of the diaphragm. Therefore, the hinge corner portion can be reinforced to improve its stress limit. As a result, the resistance of the diaphragm against film breakage can be improved.

In the third structure of the diaphragm of the present invention, it is preferable that the diaphragm has a high-level-side flat portion, a low-level-side flat portion, and a connection portion connecting the high-level-side flat portion and the low-level-side flat portion, and the connection portion has a sidewall spacer structure.

Thus, the hinge corner portion can be easily formed to be greater in film thickness than the other portions.

A condenser according to the present invention includes a pair of electrodes facing each other, wherein one of the pair of electrodes has any one of the first through third diaphragm structures or is formed on any one of the first through third diaphragm structures.

According to the condenser of the present invention, the resistance of the diaphragm against film breakage can be improved, so that it is possible to realize a condenser having high reliability.

An electret condenser microphone according to the present invention includes a pair of electrodes facing each other and an electret disposed between the pair of electrodes, wherein one of the pair of electrodes has any one of the first through third diaphragm structures or is formed on any one of the first through third diaphragm structures.

According to the electret condenser microphone of the present invention, the resistance of the diaphragm against film breakage can be improved, so that it is possible to realize an electret condenser microphone having high reliability.

A method for forming a diaphragm structure according to the present invention is a method for forming a structure including a diaphragm formed using MEMS technology, the method including the steps of: (a) forming a first film on a substrate; (b) patterning the first film; (c) forming a second film over the substrate to cover the patterned first film; (d) forming a diaphragm on the second film; (e) forming a through hole in the substrate from a side of the substrate where the diaphragm is not formed; and (f) removing the first film and the second film in a region exposed in the through hole.

According to the method for fabricating the diaphragm structure of the present invention, the second film and the diaphragm are sequentially formed to cover depressions and projections (hinge pattern) formed on the substrate upper surface by patterning the first film, so that the hinge upper corner portion of the diaphragm can be formed to have a curvature much greater than that of an upper corner portion of the second film lying thereunder. In other words, since an upper corner portion of the hinge pattern is rounded by the second film and then the diaphragm is formed on the second film, the hinge upper corner portion of the diaphragm can be certainly rounded. Therefore, the hinge upper corner portion of the diaphragm can be easily rounded, and by thickness control of the second film, the round shape of the hinge upper corner portion of the diaphragm can be easily controlled.

In the method for fabricating the diaphragm structure of the present invention, it is preferable that the first film and the second film are formed of the same material.

Thus, the removal of the first film and the second film in step (f) can be performed not individually but simultaneously, that is, easily performed.

In the method for fabricating the diaphragm structure of the present invention, the first film and the second film may also be formed on a reverse surface of the substrate where the diaphragm is not to be formed, and step (e) may include patterning the first film and the second film formed on the reverse surface and etching the substrate using the patterned first and second films on the reverse surface as a mask.

In the method for forming the diaphragm structure of the present invention, the first film and the second film may be silicon oxide films, and in step (f), the first film and the second film may be removed by etching with hydrofluoric acid.

In the method for fabricating the diaphragm structure of the present invention, the diaphragm may be a single-layer film of a polysilicon film, a single-layer film of a silicon nitride film, a multi-layer film composed of a polysilicon film and a silicon nitride film, or a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film).

It is preferable that the method for fabricating the diaphragm structure of the present invention includes between steps (b) and (c) the step of forming a sidewall spacer on a side wall of the patterned first film or includes between steps (c) and (d) the step of forming a sidewall spacer over the side wall of the patterned first film with the second film interposed therebetween.

Thus, providing the sidewall spacer on the side wall of the patterned first film, that is, on a hinge pattern side wall makes it possible to form the upper corner portion of the hinge pattern to have a bending angle of greater than 90°, in other words, makes it possible to form the upper corner portion of the hinge pattern to have an obtuse angle, so that the hinge upper corner portion of the diaphragm which is formed over the hinge pattern can also have an obtuse angle. Therefore, the hinge upper corner portion of the diaphragm can be easily formed to have an obtuse angle, and the bending angle of the hinge upper corner portion of the diaphragm can be easily controlled by the thickness control of a film which is to serve as the sidewall spacer. It is to be noted that the first film, the second film, and the sidewall spacer are formed of the same material, and in step (f), the sidewall spacer is removed together with the first film and the second film. Thus, the first film, the second film, and the sidewall spacer can be removed not individually but simultaneously, that is, can be removed easily.

It is preferable that the method for fabricating the diaphragm structure of the present invention includes between steps (c) and (d) the step of forming a sidewall spacer over the side wall of the patterned first film with the second film interposed therebetween, wherein the sidewall spacer is formed of a material different from that of the first and second films, and in step (f), the sidewall spacer is left.

Thus, providing the sidewall spacer on the side wall of the patterned first film, that is, on the hinge pattern side wall makes it possible to form the upper corner portion of the hinge pattern to have a bending angle of greater than 90°, in other words, makes it possible to form the upper corner portion of the hinge pattern to have an obtuse angle, so that the hinge upper corner portion of the diaphragm which is formed on the hinge pattern can also have an obtuse angle. Therefore, the hinge upper corner portion of the diaphragm can be easily formed to have an obtuse angle, and the bending angle of the hinge upper corner portion of the diaphragm can be easily controlled by the thickness control of a film which is to serve as the sidewall spacer. Moreover, since the sidewall spacer can be finally left outside the hinge lower corner portion of the diaphragm, the film thickness of the hinge lower corner portion can be greater compared to the other portions (for example, flat portions). In this way, the hinge lower corner portion can be reinforced by a simple method to improve its stress limit, and thus the resistance of the diaphragm against film breakage can be improved. It is to be noted that the sidewall spacer may be a silicon nitride film or a polysilicon film.

It is preferable that the method for forming the diaphragm structure of the present invention includes between steps (d) and (e) the step of forming a sidewall spacer over a side wall of the patterned first film with the second film and the diaphragm interposed therebetween, wherein the sidewall spacer is formed of a material different from that of the first and second films, and in step (f), the sidewall spacer is left.

Thus, since the sidewall spacer can be finally left inside the hinge lower corner portion of the diaphragm, the film thickness of the hinge lower corner portion can be greater compared to the other portions (for example, flat portions). Therefore, since the hinge lower corner portion can be reinforced by a simple method to improve its stress limit, the resistance of the diaphragm against film breakage can be improved. It is to be noted that the sidewall spacer may be a silicon nitride film or the polysilicon film.

It is preferable that the method for fabricating the diaphragm structure of the present invention further includes between steps (c) and (d) the step of performing a heat treatment to allow the second film to flow.

Thus, the upper corner portion and the lower corner portion of the hinge pattern covered with the second film which has been allowed to flow can be formed to have a bending angle of greater than 90°, in other words, the upper corner portion and the lower corner portion of the hinge pattern can be formed to have an obtuse angle. Therefore, the hinge upper corner portion and the hinge lower corner portion of the diaphragm which is formed over the hinge pattern can also have an obtuse angle. That is, the hinge upper corner portion and the hinge lower corner portion of the diaphragm can be easily formed to have an obtuse angle, and by controlling the temperature for the heat treatment to allow the second film to flow, the bending angle of the hinge upper corner portion and the hinge lower corner portion of the diaphragm can be easily controlled. It is to be noted that to certainly allow the second film to flow, it is preferable that the heat treatment is performed at a temperature of higher than or equal to 600° C., and the second film is a silicon oxide film doped with at least one of boron and phosphorus.

In the method for fabricating the diaphragm structure of the present invention, it is preferable that step (b) includes isotropically etching the first film by wet etching.

Thus, since grooves serving as the hinge pattern are formed by isotropically etching the first film by wet etching, the hinge pattern side wall can be rounded, so that the hinge upper corner portion and the hinge lower corner portion of the diaphragm which is formed over the hinge pattern can be rounded and have an obtuse angle. That is, the hinge upper corner portion and the hinge lower corner portion of the diaphragm can be easily rounded and formed to have an obtuse angle. Moreover, by controlling etching conditions, the bending angle and the amount of rounding of the hinge upper corner portion and the hinge lower corner portion of the diaphragm can be easily controlled. It is to be noted that in step (b), the etching may be performed such that the substrate is not exposed. Thus, since a lower base portion of the hinge pattern can be rounded, a lower base portion of the diaphragm can be rounded.

In the method for fabricating the diaphragm structure of the present invention, it is preferable that the substrate is a silicon substrate, and the method further includes between steps (b) and (c) the steps of removing the silicon substrate by a predetermined depth by etching using the patterned first film as a mask, and then performing a thermal oxidation on the silicon substrate.

Thus, on the side wall of the depressions and projections (the hinge pattern) formed on the silicon substrate by etching, a silicon oxide film is formed by thermal oxidation, and thus both the upper corner portion and the lower corner portion of the hinge pattern can be rounded, so that the hinge upper corner portion and the hinge lower corner portion of the diaphragm which is formed over the hinge pattern can also be rounded. Moreover, according to the etching conditions of the silicon substrate, the hinge pattern side wall can be formed to have inclination, and thus the hinge upper corner portion and the hinge lower corner portion of the diaphragm can be formed to have an obtuse angle. That is, the hinge upper corner portion and the hinge lower corner portion of the diaphragm can be easily rounded and formed to have an obtuse angle. It is to be noted that to certainly perform the thermal oxidation of the silicon substrate, the thermal oxidation is preferably performed at a temperature of higher than or equal to 900° C.

It is preferable that the method for forming the diaphragm structure of the present invention further includes between steps (b) and (c) the step of etching the silicon substrate using the patterned first film as a mask such that the silicon substrate is removed by a predetermined depth and an etched pattern side wall has inclination.

Thus, since the side wall of the depressions and projections (the hinge pattern) formed on the silicon substrate by etching is formed to have inclination (inclination gentler than the perpendicular), the hinge upper corner portion and the hinge lower corner portion of the diaphragm which is formed over the hinge pattern can have an obtuse angle. That is, the hinge upper corner portion and the hinge lower corner portion of the diaphragm can be easily formed to have an obtuse angle. It is to be noted that to form the hinge pattern side wall to certainly have inclination, it is preferable that the substrate is a silicon substrate whose (100) plane direction is exposed, and for etching the silicon substrate, anisotropic etching is performed by wet etching with an alkaline solution.

### EFFECTS OF THE INVENTION

According to the present invention, a hinge corner portion of a diaphragm can be easily formed to have an obtuse angle or can be easily rounded by, for example, a method in which a second film is formed after grooves serving as a hinge pattern are formed, a second film is formed after a hinge pattern side wall is formed to have inclination, or a second film is formed after the entire hinge pattern is rounded, and then the diaphragm is formed on the second film. Moreover, by controlling the steps for forming the hinge corner portion to have an obtuse angle or to be rounded, the bending angle and the round shape of the hinge corner portion are controlled to disperse the stress concentration on the hinge pattern, so that the resistance of the diaphragm against film breakage can be improved. That is, the present invention can realize a structure of a diaphragm having an excellent hinge structure and a method for forming the same.

Moreover, according to the invention, by using a method in which a sidewall spacer is formed on a hinge pattern side wall, the film thickness of a hinge corner portion of the diaphragm can be easily increased for reinforcement, and the hinge corner portion can be easily formed to have an obtuse angle or rounded. Moreover, since the bending angle and the round shape of the hinge corner portion can be controlled by controlling steps for forming the sidewall spacer, the stress concentration on the hinge corner portion can be dispersed to improve the resistance of the diaphragm against film breakage. That is, the present invention can realize a structure of a diaphragm having an excellent hinge structure and a method for forming the same.

### BRIEF DESCRIPTION OF DRAWINGS

FIGS. 1A through 1F are cross-sectional views illustrating respective steps of a method for forming a diaphragm structure according to Embodiment 1 of the present invention.

FIG. 2 is an enlarged view showing a region surrounded by a broken line of FIG. 1D.

FIGS. 3A through 3H are cross-sectional views illustrating respective steps of a method for forming a diaphragm structure according to Embodiment 2 of the present invention.

FIG. 4 is an enlarged view illustrating a process for forming a region surrounded by a broken line of FIG. 3D.

FIGS. 5A through 5H are cross-sectional views illustrating respective steps of a method for forming a diaphragm structure according to Embodiment 3 of the present invention.

FIGS. 6A through 6H are cross-sectional views illustrating respective steps of a method for forming a diaphragm structure according to Embodiment 4 of the present invention.

FIGS. 7A through 7G are cross-sectional views illustrating respective steps of a method for forming a diaphragm structure according to Embodiment 5 of the present invention.

FIGS. 8A through 8F are cross-sectional views illustrating respective steps of a method for forming a diaphragm structure according to Embodiment 6 of the present invention.

FIGS. 9A and 9B are cross-sectional views illustrating respective steps of a variation of the method for forming the diaphragm structure according to Embodiment 6 of the present invention.

FIGS. 10A through 10G are cross-sectional views illustrating respective steps of a method for forming a diaphragm structure according to Embodiment 7 of the present invention.

FIGS. 11A through 11G are cross-sectional views illustrating respective steps of a method for forming a diaphragm structure according to Embodiment 8 of the present invention.

FIG. 12 is a cross-sectional view showing an example of an electret condenser microphone to which a diaphragm structure of each of the embodiments of the present invention is applied.

FIGS. 13A through 13E are cross-sectional views illustrating respective steps of a conventional method for forming a diaphragm structure.

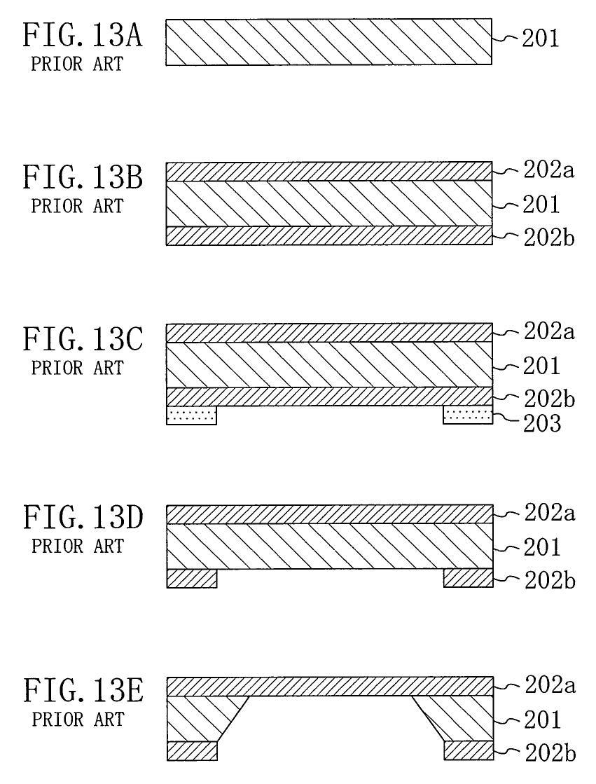

FIGS. 14A through 14G are cross-sectional views illustrating respective steps of a conventional method for forming a MEMS diaphragm structure having a hinge.

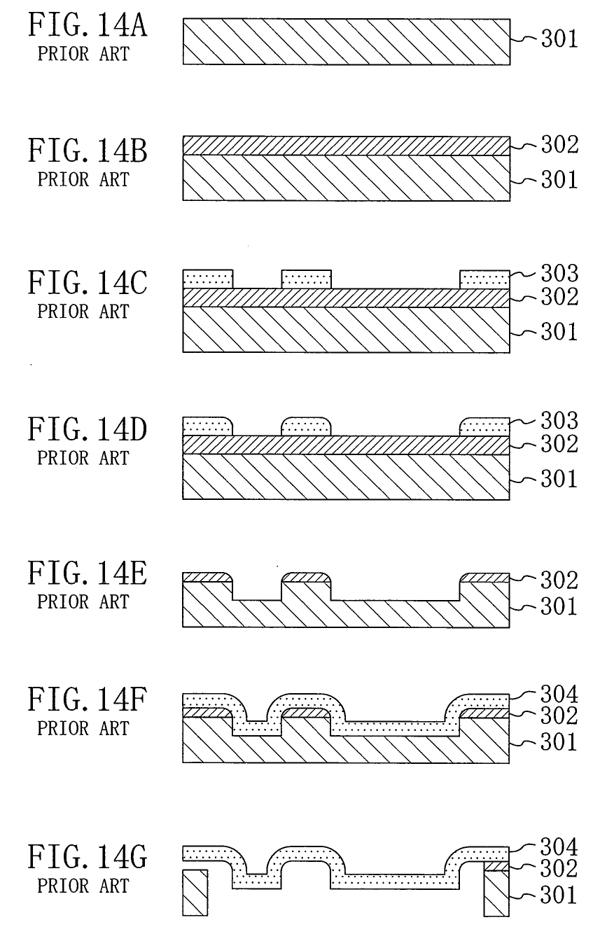

### DESCRIPTION OF REFERENCE NUMERALS

11, 21, 31, 41, 51, 61, 71, 81, 91 silicon substrate
12a, 12b, 22a, 22b, 32a, 32b, 42a, 42b, 52a, 52b, 62a, 62b, 72a, 72b, 82a, 82b first film
13a, 13b, 23a, 23b, 33a, 33b, 43a, 43b, 53a, 53b, 63a, 63b, 73a, 73b, 83a, 83b second film
14, 24, 34, 44, 54, 64, 74, 84 diaphragm
25a, 25b, 35, 45 sidewall spacer formation film
26, 36, 46 sidewall spacer
75 silicon oxide film
92 underlayer protective film
93 diaphragm electrode
93a portion of diaphragm electrode 93 located close to the center of membrane region
93b portion of diaphragm electrode 93 located on the periphery of membrane region
94 electret film
95 insulating film
96 upper surface protection film
97 fixing film electrode
98 through hole
99 air gap
100 acoustic hole

### BEST MODE FOR CARRYING OUT THE INVENTION

### Embodiment 1

A MEMS diaphragm structure having a hinge and a method for forming the same according to Embodiment 1 of the present invention will be described below with reference to the drawings.

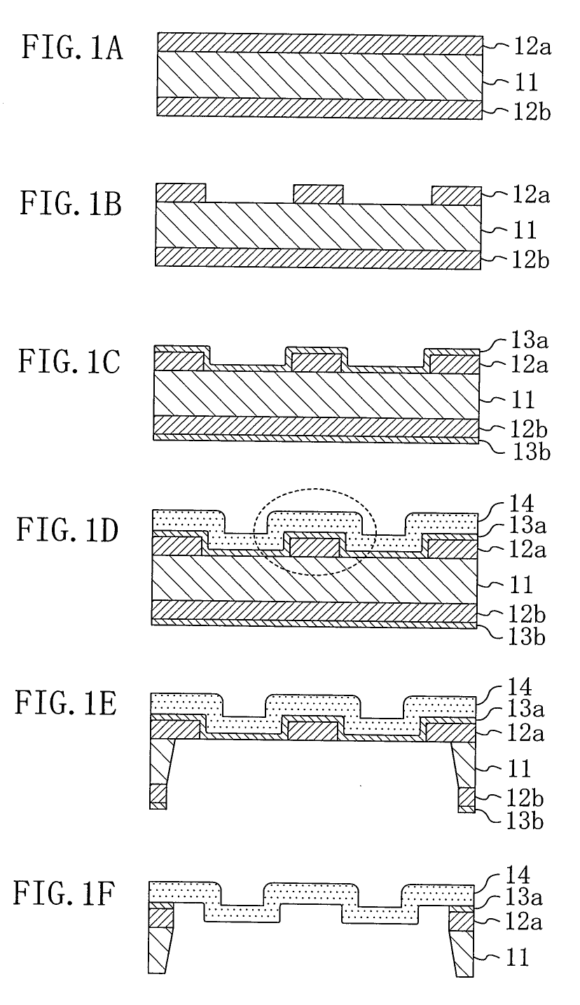

FIGS. 1A through 1F are cross-sectional views illustrating respective steps of the method for forming the diaphragm structure of Embodiment 1.

First, as illustrated with FIG. 1A, a first film 12a is formed on an upper surface of a silicon substrate 11. Here, the first film 12a desirably has a thickness of greater than or equal to about 100 nm, because the thickness of the first film 12a is a parameter which determines the height (level difference between the highest position and the lowest position in the diaphragm) of a hinge structure of a diaphragm which is to be finally formed. Moreover, since the first film 12a is finally removed by etching, the first film 12a is desirably a silicon oxide film. A silicon oxide film can be formed by thermal oxidation, low pressure CVD, plasma CVD, or the like. In the case of thermal oxidation or low pressure CVD, a silicon oxide film is formed not only on a silicon substrate upper surface but also on a silicon substrate reverse surface. Since low pressure CVD, for example, is used in the present embodiment to form the first film 12a of the silicon oxide film, a first film 12b of a silicon oxide film is also formed on a reverse surface of the silicon substrate 11.

Then, as illustrated with FIG. 1B, the first film 12a formed on the upper surface of the silicon substrate 11 is divided into a plurality of pieces by, for example, lithography and etching. Specifically, a photoresist is applied on the first film 12a and then exposed to light and developed for patterning to form a resist pattern. By using the resist pattern as a mask, the first film 12a is etched by anisotropic dry etching in a direction vertical thereto. Then, the resist pattern is removed by, for example, oxygen ashing and cleaning with a sulfuric acid hydrogen peroxide solution. In this way, the first film 12a is divided into the plurality of pieces. It is to be noted that the first film 12a in an etched region may be thinly left to such a degree that the upper surface of the silicon substrate 11 is not exposed.

Then, as illustrated with FIG. 1C, over the upper surface of the silicon substrate 11, a second film 13a is formed to cover the patterned first film 12a. Since in the present embodiment, the second film 13a is also finally removed by etching as the first films 12a and 12b, a material film composed of the same types of elemental components as those of the first films 12a and 12b, for example, a silicon oxide film is used as the second film 13a. Moreover, since in the present embodiment, for example, low pressure CVD is used to form the second film 13a of the silicon oxide film, a second film 13b of a silicon oxide film is also formed on the first film 12b on a substrate reverse surface side.

It is to be noted that in the present embodiment, the shape of the second film 13a which has been formed (that is, of the second film 13a covering depressions and projections (hinge pattern) formed on the substrate upper surface by the patterned first film 12a) determines the shape of the hinge structure of the diaphragm which is to be finally formed. Therefore, it is most desirable that low pressure CVD which is excellent in coverage characteristic and thus capable of forming a film to have the same thickness on pattern side walls and flat portions is used as a method for forming the second film 13a.

Then, as illustrated with FIG. 1D, on the second film 13a, a diaphragm 14 is formed. Here, since the diaphragm 14 is formed over the hinge pattern covered with the second film 13a, the diaphragm 14 has bends. That is, the diaphragm 14 has high-level-side flat portions over the pieces of the patterned first film 12a, low-level-side flat portions between the pieces of the patterned first film 12a, and connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. As the diaphragm 14, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 14.

Then, as illustrated with FIG. 1E, each of the silicon substrate 11, the first film 12b, and the second film 13b is partially removed. Specifically, a photoresist is applied on the second film 13b on the reverse surface side of the silicon substrate 11 and then exposed to light and developed to form a resist pattern (not shown). Then, the resist pattern is used as a mask to sequentially pattern the second film 13b and the first film 12b on the substrate reverse surface side. Then, by using the patterned second film 13b and first film 12b on the substrate reverse surface side as a mask, a predetermined portion of the silicon substrate 11 is removed by etching from the reverse surface side to form a through hole in the silicon substrate 11. To etch the silicon substrate 11, dry etching or alkaline wet etching can be used. In the case of using alkaline wet etching, a silicon substrate of the (100) plane direction is used as the silicon substrate 11, and the silicon substrate 11 is immersed in an alkaline aqueous solution which is heated to a temperature of about 70-90° C. and has a concentration of 3-30 mass % of KOH, TMAH (Tetramethyl Ammonium Hydroxide), or the like to perform anisotropic silicon wet etching on the substrate, with the (111) plane direction of the silicon being left on an etched surface. Alternatively, in the case of using dry etching, the selectivity to the second film 13b and the first film 12b which are to be used as a mask is not high (for example, the selectivity to a silicon oxide film can be increased only to about 100), but it is possible to perform etching in a direction vertical to the silicon substrate 11. By contrast, in the above-mentioned case of using wet etching, the selectivity to the second film 13b and the first film 12b which are to be used as a mask can be increased (for example, the selectivity to a silicon oxide film can be increased to about several 1000), but when the silicon substrate 11 is etched, the etched surface (pattern side wall surface) may have inclination (an inclination angle of about 54-56°). As mentioned above, since the case of using dry etching to etch the silicon substrate 11 and the case of using alkaline wet etching to etch the silicon substrate 11 show differences in etching characteristics, an optimal etching method is selected in consideration of these characteristics.

Lastly, as illustrated with FIG. 1F, the first film 12a and the second film 13a in a region exposed in the through hole of the silicon substrate 11 are removed by etching. In this way, the diaphragm (diaphragm having a hinge structure) 14 both ends of which are supported by the silicon substrate 11 and a center portion of which is in the air is formed on a substrate upper surface side. Here, in the case of using silicon oxide films as the first film 12a and the second film 13a, wet etching using a hydrofluoric acid aqueous solution as an etchant can easily remove the first film 12a and the second film 13a.

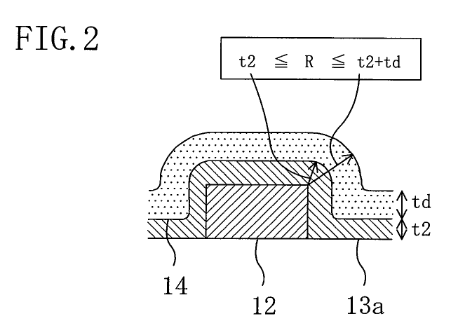

According to Embodiment 1 described above, the second film 13a and the diaphragm 14 are sequentially formed to cover the depressions and projections (the hinge pattern) formed on the substrate upper surface by the patterned first film 12a. Therefore, the hinge upper corner portions of the diaphragm 14 can be formed to have a much greater curvature (amount of rounding) than upper corner portions of the second film 13a lying thereunder. Specifically, as shown in FIG. 2 (which is an enlarged view of a region surrounded by a broken line of FIG. 1D), the amount of rounding R of the hinge upper corner portions of the diaphragm 14 can be set such that the following is satisfied: t2≦R≦(t2+td), where t2 is the thickness of the second film 13a, and td is the film thickness of the diaphragm 14. That is, since the diaphragm 14 is formed on the second film 13a after upper corner portions of the hinge pattern are rounded by the second film 13a, the hinge upper corner portions of the diaphragm 14 can be certainly rounded. Therefore, the hinge upper corner portions of the diaphragm 14 can be easily rounded, and the round shape (amount of rounding) of the hinge upper corner portions of the diaphragm 14 can be easily controlled by the thickness control of the second film 13a. Moreover, since the hinge upper corner portions of the diaphragm 14 are rounded, the stress concentration on the hinge upper corner portions can be dispersed, which makes it possible to improve the resistance of the diaphragm 14 against film breakage.

It is to be noted that in Embodiment 1, all the hinge upper corner portions of the diaphragm 14 are rounded, but alternatively, only a specific hinge upper corner portion of the diaphragm 14 may be rounded.

### Embodiment 2

A MEMS diaphragm structure having a hinge and a method for forming the same according to Embodiment 2 of the present invention will be described below with reference to the drawings.

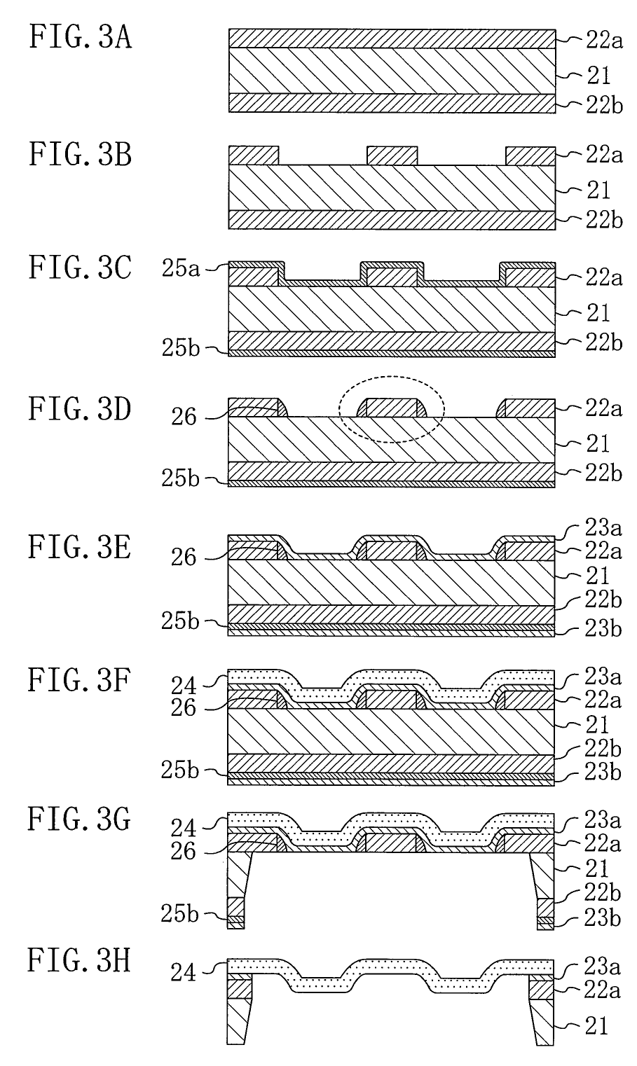

FIGS. 3A through 3H are cross-sectional views illustrating respective steps of the method for forming the diaphragm structure of Embodiment 2.

First, as illustrated with FIG. 3A, a first film 22a is formed on an upper surface of a silicon substrate 21. Here, the first film 22a desirably has a thickness of greater than or equal to about 100 nm, because the thickness of the first film 22a is a parameter which determines the height of a hinge structure of a diaphragm which is to be finally formed. Moreover, since the first film 22a is finally removed by etching, the first film 22a is desirably a silicon oxide film. A silicon oxide film can be formed by thermal oxidation, low pressure CVD, plasma CVD, or the like. In the case of using thermal oxidation or low pressure CVD, a silicon oxide film is formed not only on a silicon substrate upper surface but also on a silicon substrate reverse surface. Since low pressure CVD, for example, is used in the present embodiment to form the first film 22a of the silicon oxide film, a first film 22b of a silicon oxide film is also formed on a reverse surface of the silicon substrate 21.

Then, as illustrated with FIG. 3B, the first film 22a formed on the upper surface of the silicon substrate 21 is divided into a plurality of pieces by, for example, lithography and etching. Specifically, a photoresist is applied on the first film 22a and then exposed to light and developed for patterning to form a resist pattern. By using the resist pattern as a mask, the first film 22a is etched by anisotropic dry etching in a direction vertical thereto. Then, the resist pattern is removed by, for example, oxygen ashing and cleaning with a sulfuric acid hydrogen peroxide solution. In this way, the first film 22a is divided into the plurality of pieces. It is to be noted that the first film 22a in an etched region may be thinly left to such a degree that the upper surface of the silicon substrate 21 is not exposed.

Then, as illustrated with FIG. 3C, on the upper surface of the silicon substrate 21, a sidewall spacer formation film 25a is formed to cover the patterned first film 22a. Since in the present embodiment, the sidewall spacer formation film 25a is also finally removed by etching as the first films 22a and 22b, a material film composed of the same types of elemental components as those of the first films 22a and 22b, for example, a silicon oxide film, is used as the sidewall spacer formation film 25a. Moreover, it is most desirable that low pressure CVD which is excellent in coverage characteristic and thus capable of forming a film to have the same thickness on pattern side walls and flat portions is used as a method for forming the sidewall spacer formation film 25a. In this case, a sidewall spacer formation film 25b of a silicon oxide film is also formed on the first film 22b on a substrate reverse surface side.

Then, as illustrated with FIG. 3D, the entire surface of the sidewall spacer formation film 25a on the substrate upper surface side is etched back such that sidewall spacers 26 are formed on the side walls of the pieces of the patterned first film 22a.

Then, as illustrated with FIG. 3E, on the upper surface of the silicon substrate 21, a second film 23a is formed to cover the patterned first film 22a and sidewall spacers 26. Since in the present embodiment, the second film 23a is also finally removed by etching as the first films 22a and 22b, a material film composed of the same types of elemental components as those of the first films 22a and 22b, for example, a silicon oxide film, is used as the second film 23a. Moreover, since in the present embodiment, for example, low pressure CVD is used to form the second film 23a of the silicon oxide film, a second film 23b of a silicon oxide film is also formed on the sidewall spacer formation film 25b on the substrate reverse surface side.

It is to be noted that in the present embodiment, the shape of the second film 23a which has been formed (that is, of the second film 23a covering depressions and projections (hinge pattern) formed on the substrate upper surface by the patterned first film 22a and the sidewall spacers 26) determines the shape of the hinge structure of the diaphragm which is to be finally formed. Therefore, it is most desirable that low pressure CVD which is excellent in coverage characteristic and thus capable of forming a film to have the same thickness over the pattern side walls and flat portions is used as a method for forming the second film 23a.

Then, as illustrated with FIG. 3F, on the second film 23a, a diaphragm 24 is formed. Here, since the diaphragm 24 is formed over the hinge pattern covered with the second film 23a, the diaphragm 24 has bends. That is, the diaphragm 24 has high-level-side flat portions over the pieces of the patterned first film 22a, low-level-side flat portions between the pieces of the patterned first film 22a, and connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. As the diaphragm 24, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 24.

Then, as illustrated with FIG. 3G, each of the silicon substrate 21, the first film 22b, the sidewall spacer formation film 25b, and the second film 23b is partially removed. Specifically, a photoresist is applied on the second film 23b on the reverse surface side of the silicon substrate 21 and then exposed to light and developed to form a resist pattern (not shown). Then, the resist pattern is used as a mask to sequentially pattern the second film 23b, the sidewall spacer formation film 25b, and the first film 22b on the substrate reverse surface side. Then, by using the patterned second film 23b, sidewall spacer formation film 25b, and first film 22b on the substrate reverse surface side as a mask, a predetermined portion of the silicon substrate 21 is removed by etching from the reverse surface side to form a through hole in the silicon substrate 21. To etch the silicon substrate 21, dry etching or alkaline wet etching can be used. In the case of using alkaline wet etching, a silicon substrate of the (100) plane direction is used as the silicon substrate 21, and the silicon substrate 21 is immersed in an alkaline aqueous solution which is heated to a temperature of about 70-90° C. and has a concentration of 3-30 mass % of KOH, TMAH, or the like to perform anisotropic silicon wet etching on the substrate, with the (111) plane direction of the silicon being left on an etched surface. Alternatively, in the case of using dry etching, the selectivity to the second film 23b, the sidewall spacer formation film 25b, and the first film 22b which are to be used as a mask is not high (for example, the selectivity to a silicon oxide film can be increased only to about 100), but it is possible to perform etching in a direction vertical to the silicon substrate 21. By contrast, in the above-mentioned case of using wet etching, the selectivity to the second film 23b, the sidewall spacer formation film 25b, and the first film 22b which are to be used as a mask can be increased (for example, the selectivity to a silicon oxide film can be increased to about several 1000), but when the silicon substrate 21 is etched, the etched surface (pattern side wall surface) may have inclination (an inclination angle of about 54-56°). As mentioned above, since the case of using dry etching to etch the silicon substrate 21 and the case of using alkaline wet etching to etch the silicon substrate 21 show differences in etching characteristics, an optimal etching method is selected in consideration of these characteristics.

Lastly, as illustrated with FIG. 3H, the first film 22a, the sidewall spacers 26, and the second film 23a in a region exposed in the through hole of the silicon substrate 21 are removed by etching. In this way, the diaphragm (diaphragm having a hinge structure) 24 both ends of which are supported by the silicon substrate 21 and a center portion of which is in the air is formed on a substrate upper surface side. Here, in the case of using silicon oxide films as the first film 22a, the sidewall spacers 26 (the sidewall spacer formation film 25a), and the second film 23a, wet etching using a hydrofluoric acid aqueous solution as an etchant can easily remove the first film 22a, the sidewall spacers 26, and the second film 23a.

According to Embodiment 2 described above, the second film 23a and the diaphragm 24 are sequentially formed to cover the depressions and projections (the hinge pattern) formed on the substrate upper surface by the patterned first film 22a. Therefore, the hinge upper corner portions of the diaphragm 24 can be formed to have a much greater curvature (amount of rounding) than upper corner portions of the second film 23a lying thereunder. That is, since the diaphragm 24 is formed on the second film 23a after upper corner portions of the hinge pattern are rounded by the second film 23a, the hinge upper corner portions of the diaphragm 24 can be certainly rounded. Moreover, providing the sidewall spacers 26 on the hinge pattern side walls allows the upper corner portions of the hinge pattern to have a bending angle greater than 90°, in other words, allows the upper corner portions of the hinge pattern to have an obtuse angle, so that the hinge upper corner portions of the diaphragm 24 which is formed on the hinge pattern can also have an obtuse angle. Therefore, the hinge upper corner portions of the diaphragm 24 can be easily rounded and formed to have an obtuse angle. The round shape (amount of rounding) of the hinge upper corner portions of the diaphragm 24 can be easily controlled by the thickness control of the second film 23a, and the bending angle of the hinge upper corner portions of the diaphragm 24 can be easily controlled by the thickness control of the sidewall spacer formation film 25a which is to serve as the sidewall spacers 26. Moreover, since the hinge upper corner portions of the diaphragm 24 are rounded and formed to have an obtuse angle, the stress concentration on the hinge upper corner portions can be dispersed, which makes it possible to improve the resistance of the diaphragm 24 against film breakage.

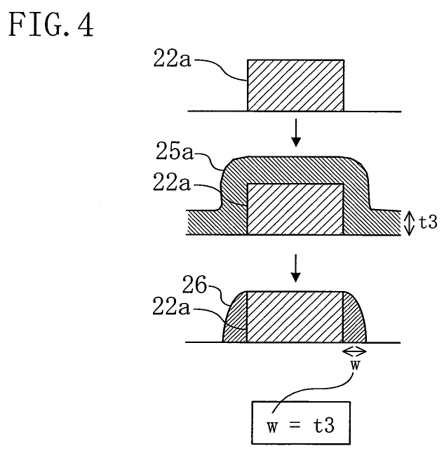

It is to be noted that in Embodiment 2, the shape of hinge lower corner portions of the diaphragm 24 can be controlled as follows. That is, as shown in FIG. 4 (which is an enlarged view illustrating a process for forming a region surrounded by a broken line of FIG. 3D), the shape of the hinge lower corner portions of the diaphragm 24 depends on the width w of the sidewall spacers 206, while a relationship that the sidewall spacer width w is equal to the thickness t3 of the sidewall spacer formation film 25a (w=t3) is satisfied. Therefore, by controlling the thickness t3 of the sidewall spacer formation film 25a, the shape of the hinge lower corner portions of the diaphragm 24 can be controlled.

Moreover, in Embodiment 2, between the step of patterning the first film 22a of FIG. 3B and the step of forming the second film 23a of FIG. 3E, the sidewall spacers 26 are formed on the side walls of each piece of the patterned first film 22a (see FIGS. 3C and 3D). However, the sidewall spacers may be formed not necessarily before the step of forming the second film 23a of FIG. 3E. Instead, between the step of forming the second film 23a of FIG. 3E and the step of forming the diaphragm 24 of FIG. 3F, the sidewall spacers may be formed over the side walls of each of the pieces of the patterned first film 22a with the second film 23a interposed therebetween. As a method for forming the sidewall spacers, steps the same as those illustrated with FIGS. 3C and 3D may be used.

It is to be noted that in Embodiment 2, all the hinge upper corner portions of the diaphragm 24 are rounded and formed to have an obtuse angle, but alternatively, only a specific hinge upper corner portion of the diaphragm 24 may be rounded and formed to have an obtuse angle.

### Embodiment 3

A MEMS diaphragm structure having a hinge and a method for forming the same according to Embodiment 3 of the present invention will be described below with reference to the drawings.

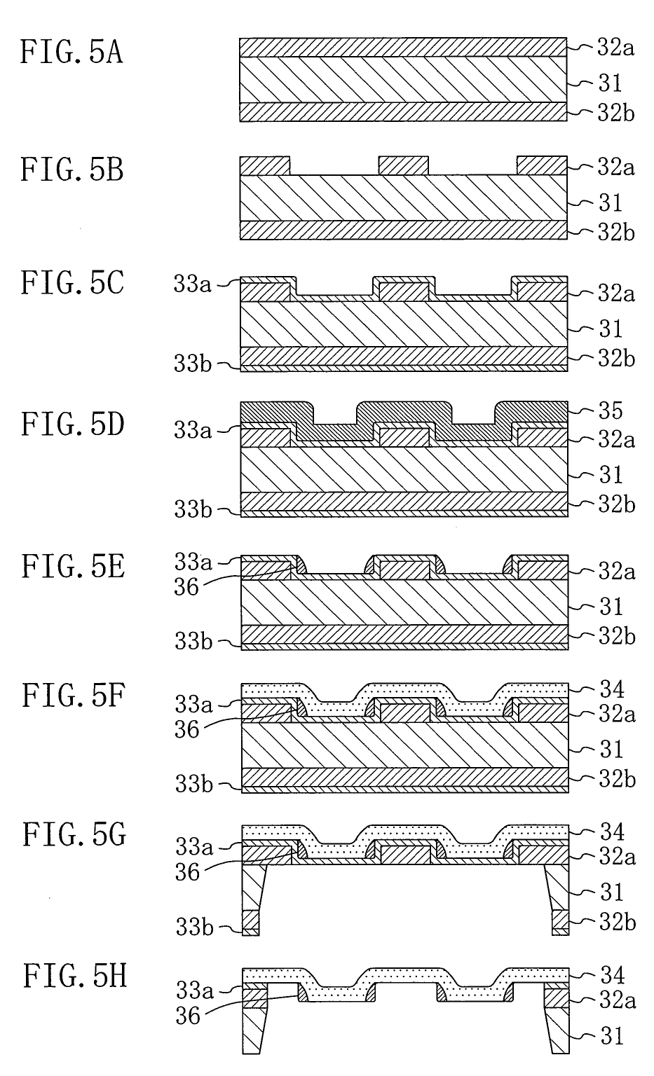

FIGS. 5A through 5H are cross-sectional views illustrating respective steps of the method for forming the diaphragm structure of Embodiment 3.

First, as illustrated with FIG. 5A, a first film 32a is formed on an upper surface of a silicon substrate 31. Here, the first film 32a desirably has a thickness of greater than or equal to about 100 nm, because the thickness of the first film 32a is a parameter which determines the height of a hinge structure of a diaphragm which is to be finally formed. Moreover, since the first film 32a is finally removed by etching, the first film 32a is desirably a silicon oxide film. A silicon oxide film can be formed by thermal oxidation, low pressure CVD, plasma CVD, or the like. In the case of using thermal oxidation or low pressure CVD, a silicon oxide film is formed not only on a silicon substrate upper surface but also on a silicon substrate reverse surface. Since low pressure CVD, for example, is used in the present embodiment to form the first film 32a of the silicon oxide film, a first film 32b of a silicon oxide film is also formed on a reverse surface of the silicon substrate 31.

Then, as illustrated with FIG. 5B, the first film 32a formed on the upper surface of the silicon substrate 31 is divided into a plurality of pieces by, for example, lithography and etching. Specifically, a photoresist is applied on the first film 32a and then exposed to light and developed for patterning to form a resist pattern. By using the resist pattern as a mask, the first film 32a is etched by anisotropic dry etching in a direction vertical thereto. Then, the resist pattern is removed by, for example, oxygen ashing and cleaning with a sulfuric acid hydrogen peroxide solution. In this way, the first film 32a is divided into the plurality of pieces. It is to be noted that the first film 32a in an etched region may be thinly left to such a degree that the upper surface of the silicon substrate 31 is not exposed.

Then, as illustrated with FIG. 5C, on the upper surface of the silicon substrate 31, a second film 33a is formed to cover the patterned first film 32a. Since in the present embodiment, the second film 33a is also finally removed by etching as the first films 32a and 32b, a material film composed of the same types of elemental components as those of the first films 32a and 32b, for example, a silicon oxide film, is used as the second film 33a. Moreover, since in the present embodiment, low pressure CVD, for example, is used to form the second film 33a of the silicon oxide film, a second film 33b of a silicon oxide film is also formed on the first film 32b on a substrate reverse surface side.

It is to be noted that in the present embodiment, the shape of the second film 33a which has been formed (that is, of the second film 33a covering the patterned first film 32a) determines the shape of the hinge structure of the diaphragm which is to be finally formed. Therefore, it is most desirable that low pressure CVD which is excellent in coverage characteristic and thus capable of forming a film to have the same thickness on pattern side walls and flat portions is used as a method for forming the second film 33a.

Then, as illustrated with FIG. 5D, on the second film 33a, a sidewall spacer formation film 35 is formed. In the present embodiment, to leave part of the sidewall spacer formation film 35 as sidewall spacers described later, a material film composed of different types of elemental components from those of the first films 32a and 32b and the second films 33a and 33b, such as a silicon nitride film or a polysilicon film, or a material film composed of the same types of elemental components as those of a diaphragm 34 is used as the sidewall spacer formation film 35. Moreover, it is most desirable that low pressure CVD which is excellent in coverage characteristic and thus capable of forming a film to have the same thickness over the pattern side walls and flat portions is used as a method for forming the sidewall spacer formation film 35. In this case, also on the second film 33b on a substrate reverse surface side, a sidewall spacer formation film is formed.

Then, as illustrated with FIG. 5E, the entire surface of the sidewall spacer formation film 35 on a substrate upper surface side is etched back such that sidewall spacers 36 are formed over the side walls of the pieces of the patterned first film 32a with the second film 33a interposed therebetween.

Then, as illustrated with FIG. 5F, on the second film 33a and the sidewall spacers 36, the diaphragm 34 is formed. Here, since the diaphragm 34 is formed over a hinge pattern covered with the second film 33a and the sidewall spacers 36, the diaphragm 34 has bends. That is, the diaphragm 34 has high-level-side flat portions over the pieces of the patterned first film 32a, low-level-side flat portions between the pieces of the patterned first film 32a, and connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. As the diaphragm 34, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 34.

Then, as illustrated with FIG. 5G, each of the silicon substrate 31, the first film 32b, and the second film 33b is partially removed. Specifically, a photoresist is applied on the second film 33b on the reverse surface side of the silicon substrate 31 and then exposed to light and developed to form a resist pattern (not shown). Then, the resist pattern is used as a mask to sequentially pattern the second film 33b and the first film 32b on the substrate reverse surface side. Then, by using the patterned second film 33b and first film 32b on the substrate reverse surface side as a mask, a predetermined portion of the silicon substrate 31 is removed by etching from the reverse surface side to form a through hole in the silicon substrate 31. To etch the silicon substrate 31, dry etching or alkaline wet etching can be used. In the case of using alkaline wet etching, a silicon substrate of the (100) plane direction is used as the silicon substrate 31, and the silicon substrate 31 is immersed in an alkaline aqueous solution which is heated to a temperature of about 70-90° C. and has a concentration of 3-30 mass % of KOH, TMAH, or the like to perform anisotropic silicon wet etching on the substrate, with the (111) plane direction of the silicon being left on an etched surface. Alternatively, in the case of using dry etching, the selectivity to the second film 33b and the first film 32b which are to be used as a mask is not high (for example, the selectivity to a silicon oxide film can be increased only to about 100), but it is possible to perform etching in a direction vertical to the silicon substrate 31. By contrast, in the above-mentioned case of using wet etching, the selectivity to the second film 33b and the first film 32b which are to be used as a mask can be increased (for example, the selectivity to a silicon oxide film can be increased to about several 1000), but when the silicon substrate 31 is etched, the etched surface (pattern side wall surface) may have inclination (an inclination angle of about 54-56°). As mentioned above, since the case of using dry etching to etch the silicon substrate 31 and the case of using alkaline wet etching to etch the silicon substrate 31 show differences in etching characteristics, an optimal etching method is selected in consideration of these characteristics.

Lastly, as illustrated with FIG. 5H, the first film 32a and the second film 33a in a region exposed in the through hole of the silicon substrate 31 are removed by etching. Here, the sidewall spacers 36 are left outside the hinge lower corner portions of the diaphragm 34. In other words, the connection portions of the diaphragm 34 have a sidewall spacer structure. In this way, the diaphragm (diaphragm having a hinge structure) 34 both ends of which are supported by the silicon substrate 31 and a center portion of which is in the air is formed on a substrate upper surface side. Here, in the case of using silicon oxide films as the first film 32a and the second film 33a, wet etching using a hydrofluoric acid aqueous solution as an etchant can easily remove the first film 32a and the second film 33a.

According to Embodiment 3 described above, the second film 33a and the diaphragm 34 are sequentially formed to cover depressions and projections (the hinge pattern) formed on the substrate upper surface by the patterned first film 32a. Therefore, the hinge upper corner portions of the diaphragm 34 can be formed to have a much greater curvature (amount of rounding) than upper corner portions of the second film 33a lying thereunder. That is, since the diaphragm 34 is formed on the second film 33a after upper corner portions of the hinge pattern are rounded by the second film 33a, the hinge upper corner portions of the diaphragm 34 can be certainly rounded.

Moreover, according to Embodiment 3, providing the sidewall spacers 36 over the hinge pattern side walls with the second film 33a interposed therebetween allows the upper corner portions of the hinge pattern to have a bending angle greater than 90°, in other words, allows the upper corner portions of the hinge pattern to have an obtuse angle, so that the hinge upper corner portions of the diaphragm 34 which is formed on the hinge pattern can also have an obtuse angle. Therefore, the hinge upper corner portions of the diaphragm 34 can be easily rounded and formed to have an obtuse angle.

Moreover, according to Embodiment 3, the round shape (amount of rounding) of the hinge upper corner portions of the diaphragm 34 can be easily controlled by the thickness control of the second film 33a, and the bending angle of the hinge upper corner portions of the diaphragm 34 can be easily controlled by the thickness control of the sidewall spacer formation film 35 which is to serve as the sidewall spacers 36. Moreover, since the hinge upper corner portions of the diaphragm 34 are rounded and formed to have an obtuse angle, the stress concentration on the hinge upper corner portions can be dispersed, which makes it possible to improve the resistance of the diaphragm 34 against film breakage.

Moreover, according to Embodiment 3, since the sidewall spacers 36 can be finally left outside the hinge lower corner portions of the diaphragm 34, the film thickness of the hinge lower corner portions including the sidewall spacers 36 can be greater than the film thickness of the other portions (for example, flat portions). In this way, the hinge lower corner portions can be reinforced by a simple method to improve their stress limit. This can improve the resistance of the diaphragm 34 against film breakage. Moreover, since the size of the sidewall spacers 36 for reinforcing the hinge lower corner portions depends on the thickness of the sidewall spacer formation film 35 when it was first formed, the amount of reinforcements of the hinge lower corner portions can be controlled by the thickness control of the sidewall spacer formation film 35.

It is to be noted that in Embodiment 3, all the hinge upper corner portions of the diaphragm 34 are rounded and formed to have an obtuse angle, but alternatively, only a specific hinge upper corner portion of the diaphragm 34 may be rounded and formed to have an obtuse angle.

In Embodiment 3, the sidewall spacers 36 are provided outside all the hinge lower corner portions of the diaphragm 34. However, the sidewall spacers 36 may be provided outside only a specific hinge lower corner portion of the diaphragm 34.

### Embodiment 4

A MEMS diaphragm structure having a hinge and a method for forming the same according to Embodiment 4 of the present invention will be described below with reference to the drawings.

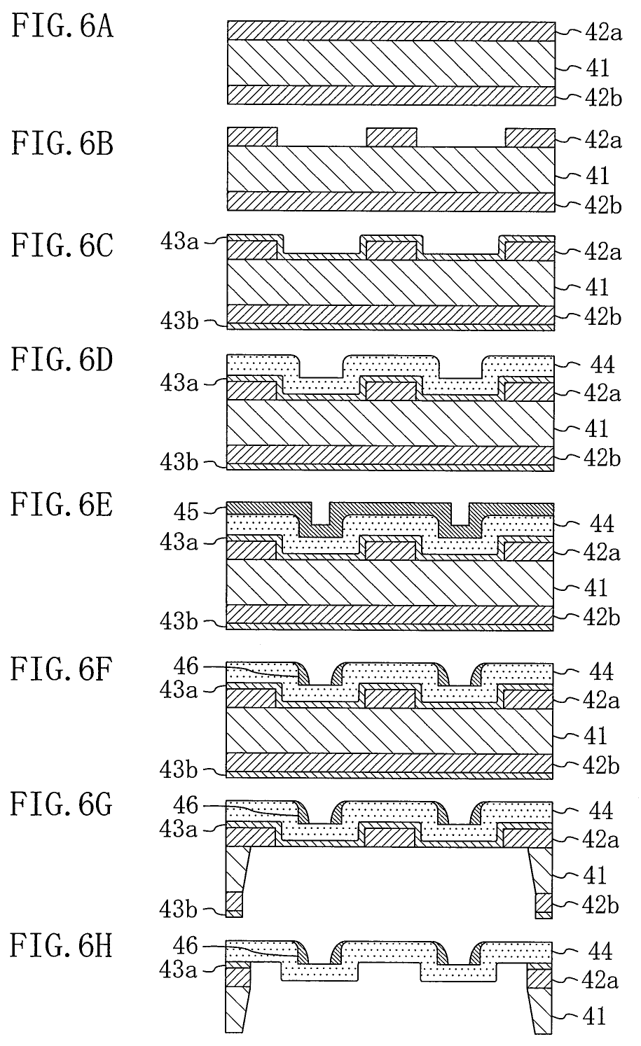

FIGS. 6A through 6H are cross-sectional views illustrating respective steps of the method for forming the diaphragm structure of Embodiment 4.

First, as illustrated with FIG. 6A, a first film 42a is formed on an upper surface of a silicon substrate 41. Here, the first film 42a desirably has a thickness of greater than or equal to about 100 nm, because the thickness of the first film 42a is a parameter which determines the height of a hinge structure of a diaphragm which is to be finally formed. Moreover, since the first film 42a is finally removed by etching, the first film 42a is desirably a silicon oxide film. A silicon oxide film can be formed by thermal oxidation, low pressure CVD, plasma CVD, or the like. In the case of using thermal oxidation or low pressure CVD, a silicon oxide film is formed not only on a silicon substrate upper surface but also on a silicon substrate reverse surface. Since low pressure CVD, for example, is used in the present embodiment to form the first film 42a of the silicon oxide film, a first film 42b of a silicon oxide film is also formed on a reverse surface of the silicon substrate 41.

Then, as illustrated with FIG. 6B, the first film 42a formed on the upper surface of the silicon substrate 41 is divided into a plurality of pieces by, for example, lithography and etching. Specifically, a photoresist is applied on the first film 42a and then exposed to light and developed for patterning to form a resist pattern. By using the resist pattern as a mask, the first film 42a is etched by anisotropic dry etching in a direction vertical thereto. Then, the resist pattern is removed by, for example, oxygen ashing and cleaning with a sulfuric acid hydrogen peroxide solution. In this way, the first film 42a is divided into the plurality of pieces. It is to be noted that the first film 42a in an etched region may be thinly left to such a degree that the upper surface of the silicon substrate 41 is not exposed.

Then, as illustrated with FIG. 6C, on the upper surface of the silicon substrate 41, a second film 43a is formed to cover the patterned first film 42a. Since in the present embodiment, the second film 43a is also finally removed by etching as the first films 42a and 42b, a material film composed of the same types of elemental components as those of the first films 42a and 42b, for example, a silicon oxide film, is used as the second film 43a. Moreover, since in the present embodiment, low pressure CVD, for example, is used to form the second film 43a of the silicon oxide film, a second film 43b of a silicon oxide film is also formed on the first film 42b on a substrate reverse surface side.

It is to be noted that in the present embodiment, the shape of the second film 43a which has been formed (that is, of the second film 43a covering the patterned first film 42a) determines the shape of the hinge structure of the diaphragm which is to be finally formed. Therefore, it is most desirable that low pressure CVD which is excellent in coverage characteristic and thus capable of forming a film to have the same thickness on pattern side walls and flat portions is used as a method for forming the second film 43a.

Then, as illustrated with FIG. 6D, on the second film 43a, the diaphragm 44 is formed. Here, since the diaphragm 44 is formed over a hinge pattern covered with the second film 43a, the diaphragm 44 has bends. That is, the diaphragm 44 has high-level-side flat portions over the pieces of the patterned first film 42a, low-level-side flat portions between the pieces of the patterned first film 42a, and connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. As the diaphragm 44, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 44.

Then, as illustrated with FIG. 6E, on the diaphragm 44, a sidewall spacer formation film 45 is formed. In the present embodiment, to leave part of the sidewall spacer formation film 45 as sidewall spacers described later, a material film composed of different types of elemental components from those of the first films 42a and 42b and the second films 43a and 43b, such as a silicon nitride film or a polysilicon film, or a material film composed of the same types of elemental components as those of a diaphragm 44 is used as the sidewall spacer formation film 45. Moreover, it is most desirable that low pressure CVD which is excellent in coverage characteristic and thus capable of forming a film to have the same thickness over the pattern side walls and flat portions is used as a method for forming the sidewall spacer formation film 45. In this case, also on the second film 43b on a substrate reverse surface side, a sidewall spacer formation film is formed.

Then, as illustrated with FIG. 6F, the entire surface of the sidewall spacer formation film 45 on a substrate upper surface side is etched back such that sidewall spacers 46 are formed over the side walls of the pieces of the patterned first film 42a with the second film 43a and the diaphragm 44 interposed therebetween.

Then, as illustrated with FIG. 6G, each of the silicon substrate 41, the first film 42b, and the second film 43b is partially removed. Specifically, a photoresist is applied on the second film 43b on the reverse surface side of the silicon substrate 41 and then exposed to light and developed to form a resist pattern (not shown). Then, the resist pattern is used as a mask to sequentially pattern the second film 43b and the first film 42b on the substrate reverse surface side. Then, by using the patterned second film 43b and first film 42b on the substrate reverse surface side as a mask, a predetermined portion of the silicon substrate 41 is removed by etching from the reverse surface side to form a through hole in the silicon substrate 41. To etch the silicon substrate 41, dry etching or alkaline wet etching can be used. In the case of using alkaline wet etching, a silicon substrate of the (100) plane direction is used as the silicon substrate 41, and the silicon substrate 41 is immersed in an alkaline aqueous solution which is heated to a temperature of about 70-90° C. and has a concentration of 3-30 mass % of KOH, TMAH, or the like to perform anisotropic silicon wet etching on the substrate, with the (111) plane direction of the silicon being left on an etched surface. Alternatively, in the case of using dry etching, the selectivity to the second film 43b and the first film 42b which are to be used as a mask is not high (for example, the selectivity to a silicon oxide film can be increased only to about 100), but it is possible to perform etching in a direction vertical to the silicon substrate 41. By contrast, in the above-mentioned case of using wet etching, the selectivity to the second film 43b and the first film 42b which are to be used as a mask can be increased (for example, the selectivity to a silicon oxide film can be increased to about several 1000), but when the silicon substrate 41 is etched, the etched surface (pattern side wall surface) may have inclination (an inclination angle of about 54-56°). As mentioned above, since the case of using dry etching to etch the silicon substrate 41 and the case of using alkaline wet etching to etch the silicon substrate 41 show differences in etching characteristics, an optimal etching method is selected in consideration of these characteristics.

Lastly, as illustrated with FIG. 6H, the first film 42a and the second film 43a in a region exposed in the through hole of the silicon substrate 41 are removed by etching. Here, the sidewall spacers 46 are left inside the hinge lower corner portions of the diaphragm 44. In other words, the connection portions of the diaphragm 44 have a sidewall spacer structure. In this way, the diaphragm (diaphragm having a hinge structure) 44 both ends of which are supported by the silicon substrate 41 and a center portion of which is in the air is formed on a substrate upper surface side. Here, in the case of using silicon oxide films as the first film 42a and the second film 43a, wet etching using a hydrofluoric acid aqueous solution as an etchant can easily remove the first film 42a and the second film 43a.

According to Embodiment 4 described above, the second film 43a and the diaphragm 44 are sequentially formed to cover depressions and projections (the hinge pattern) formed on the substrate upper surface by the patterned first film 42a. Therefore, the hinge upper corner portions of the diaphragm 44 can be formed to have a much greater curvature (amount of rounding) than upper corner portions of the second film 43a lying thereunder. That is, since the diaphragm 44 is formed on the second film 43a after upper corner portions of the hinge pattern are rounded by the second film 43a, the hinge upper corner portions of the diaphragm 44 can be certainly rounded. Moreover, by the thickness control of the second film 43a, the round shape (amount of rounding) of the hinge upper corner portions of the diaphragm 44 can be easily controlled. Moreover, since the hinge upper corner portions of the diaphragm 44 are rounded, the stress concentration on the hinge upper corner portions can be dispersed, which makes it possible to improve the resistance of the diaphragm 44 against film breakage.

Moreover, according to Embodiment 4, since the sidewall spacers 46 can be finally left inside the hinge lower corner portions of the diaphragm 44, the film thickness of the hinge lower corner portions including the sidewall spacers 46 can be greater than the film thickness of the other portions (for example, flat portions). In this way, the hinge lower corner portions can be reinforced by a simple method to improve their stress limit. This can improve the resistance of the diaphragm 44 against film breakage. Moreover, since the size of the sidewall spacers 46 for reinforcing the hinge lower corner portions depends on the thickness of the sidewall spacer formation film 45 when it was first formed, the amount of reinforcements of the hinge lower corner portions can be controlled by the thickness control of the sidewall spacer formation film 45.

It is to be noted that in Embodiment 4, all the hinge upper corner portions of the diaphragm 44 are rounded, but alternatively, only a specific hinge upper corner portion of the diaphragm 44 may be rounded.

In Embodiment 4, the sidewall spacers 46 are provided inside all the hinge lower corner portions of the diaphragm 44. However, the sidewall spacers 46 may be provided inside only a specific hinge lower corner portion of the diaphragm 44.

### Embodiment 5

A MEMS diaphragm structure having a hinge and a method for forming the same according to Embodiment 5 of the present invention will be described below with reference to the drawings.

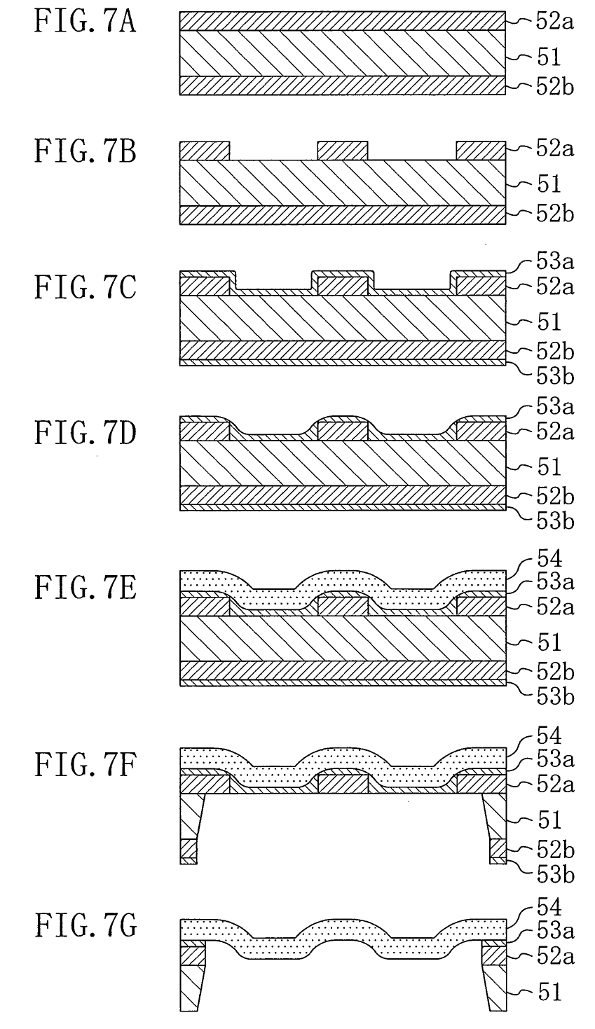

FIGS. 7A through 7G are cross-sectional views illustrating respective steps of the method for forming the diaphragm structure of Embodiment 5.

First, as illustrated with FIG. 7A, a first film 52a is formed on an upper surface of a silicon substrate 51. Here, the first film 52a desirably has a thickness of greater than or equal to about 100 nm, because the thickness of the first film 52a is a parameter which determines the height of a hinge structure of a diaphragm which is to be finally formed. Moreover, since the first film 52a is finally removed by etching, the first film 52a is desirably a silicon oxide film. A silicon oxide film can be formed by thermal oxidation, low pressure CVD, plasma CVD, or the like. In the case of using thermal oxidation or low pressure CVD, a silicon oxide film is formed not only on a silicon substrate upper surface but also on a silicon substrate reverse surface. Since low pressure CVD, for example, is used in the present embodiment to form the first film 52a of the silicon oxide film, a first film 52b of a silicon oxide film is also formed on a reverse surface of the silicon substrate 51.

Then, as illustrated with FIG. 7B, the first film 52a formed on the upper surface of the silicon substrate 51 is divided into a plurality of pieces by, for example, lithography and etching. Specifically, a photoresist is applied on the first film 52a and then exposed to light and developed for patterning to form a resist pattern. By using the resist pattern as a mask, the first film 52a is etched by anisotropic dry etching in a direction vertical thereto. Then, the resist pattern is removed by, for example, oxygen ashing and cleaning with a sulfuric acid hydrogen peroxide solution. In this way, the first film 52a is divided into the plurality of pieces. It is to be noted that the first film 52a in an etched region may be thinly left to such a degree that the upper surface of the silicon substrate 51 is not exposed.

Then, as illustrated with FIG. 7C, on the upper surface of the silicon substrate 51, a second film 53a is formed to cover the patterned first film 52a. Since in the present embodiment, the second film 53a is also finally removed by etching as the first films 52a and 52b, a material film composed of the same types of elemental components as those of the first films 52a and 52b, for example, a silicon oxide film, is used as the second film 53a. Moreover, since in the present embodiment, low pressure CVD, for example, is used to form the second film 53a of the silicon oxide film, a second film 53b of a silicon oxide film is also formed on the first film 52b on a substrate reverse surface side.

It is to be noted that in the present embodiment, to allow the second film 53a to flow by a heat treatment which will be described later, the second film 53a formed by, for example, a silicon oxide film is doped to have a concentration within the range of 1-7 wt % of an impurity, for example, at least one of boron and phosphorus.

Then, as illustrated with FIG. 7D, the heat treatment is performed, for example, at a high temperature of 600° C. or higher to allow the second film 53a to flow. As to the second film 53a doped with an impurity such as boron or phosphorus, as its impurity concentration increases, the temperature at which the second film 53a is allowed to flow decreases, and the flowability in the heat treatment improves. Therefore, the bending angle and the amount of rounding of the hinge corner portions, the amount of inclination of hinge pattern side walls, and the like can be controlled by the impurity concentration or the heating temperature of the second film 53a.

Then, as illustrated with FIG. 7E, on the second film 53a which has been allowed to flow, a diaphragm 54 is formed. Here, since the diaphragm 54 is formed over a hinge pattern covered with the second film 53a, the diaphragm 54 has bends. That is, the diaphragm 54 has high-level-side flat portions over the pieces of the patterned first film 52a, low-level-side flat portions between the pieces of the patterned first film 52a, and connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. In the present embodiment, since the second film 53a covering the hinge pattern is allowed to flow, not only the hinge upper corner portions and the hinge lower corner portions are rounded and formed to have an obtuse angle, but also each of the high-level-side flat portions, the low-level-side flat portions, and connection portions is also rounded. As the diaphragm 54, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 54.

Then, as illustrated with FIG. 7F, each of the silicon substrate 51, the first film 52b, and the second film 53b is partially removed. Specifically, a photoresist is applied on the second film 53b on the reverse surface side of the silicon substrate 51 and then exposed to light and developed to form a resist pattern (not shown). Then, the resist pattern is used as a mask to sequentially pattern the second film 53b and the first film 52b on the substrate reverse surface side. Then, by using the patterned second film 53b and first film 52b on the substrate reverse surface side as a mask, a predetermined portion of the silicon substrate 51 is removed by etching from the reverse surface side to form a through hole in the silicon substrate 51. To etch the silicon substrate 51, dry etching or alkaline wet etching can be used. In the case of using alkaline wet etching, a silicon substrate of the (100) plane direction is used as the silicon substrate 51, and the silicon substrate 51 is immersed in an alkaline aqueous solution which is heated to a temperature of about 70-90° C. and has a concentration of 3-30 mass % of KOH, TMAH, or the like to perform anisotropic silicon wet etching on the substrate, with the (111) plane direction of the silicon being left on an etched surface. Alternatively, in the case of using dry etching, the selectivity to the second film 53b and the first film 52b which are to be used as a mask is not high (for example, the selectivity to a silicon oxide film can be increased only to about 100), but it is possible to perform etching in a direction vertical to the silicon substrate 51. By contrast, in the above-mentioned case of using wet etching, the selectivity to the second film 53b and the first film 52b which are to be used as a mask can be increased (for example, the selectivity to a silicon oxide film can be increased to about several 1000), but when the silicon substrate 51 is etched, the etched surface (pattern side wall surface) may have inclination (an inclination angle of about 54-56°). As mentioned above, since the case of using dry etching to etch the silicon substrate 51 and the case of using alkaline wet etching to etch the silicon substrate 51 show differences in etching characteristics, an optimal etching method is selected in consideration of these characteristics.

Lastly, as illustrated with FIG. 7G, the first film 52a and the second film 53a in a region exposed in the through hole of the silicon substrate 51 are removed by etching. In this way, the diaphragm (diaphragm having a hinge structure) 54 both ends of which are supported by the silicon substrate 51 and a center portion of which is in the air is formed on a substrate upper surface side. Here, in the case of using silicon oxide films as the first film 52a and the second film 53a, wet etching using a hydrofluoric acid aqueous solution as an etchant can easily remove the first film 52a and the second film 53a.

According to Embodiment 5 described above, the second film 53a is formed to cover depressions and projections (the hinge pattern) formed on the substrate upper surface by the patterned first film 52a, and then the second film 53a is allowed to flow. Therefore, upper corner portions and lower corner portions of the hinge pattern covered by the second film 53a which has been allowed to flow can be rounded and the bending angle of each corner portion can be greater than 90°. In other words, the upper corner portions and the lower corner portions of the hinge pattern can be rounded and formed to have an obtuse angle. Therefore, the hinge upper corner portions and the hinge lower corner portions of the diaphragm 54 which is formed on the hinge pattern can also be rounded and have an obtuse angle. That is, the hinge upper corner portions and the hinge lower corner portions of the diaphragm 54 can be easily rounded and formed to have an obtuse angle, and by controlling the temperature for the heat treatment to allow the second film 53a to flow and the impurity concentration of the second film 53a, the bending angle of the hinge upper corner portions and the hinge lower corner portions of the diaphragm 54 can be easily controlled.

It is to be noted that in Embodiment 5, to certainly allow the second film 53a to flow, it is preferable that the temperature for heat treatment to allow the second film 53a to flow is 600° C. or higher, and the second film 53a is a silicon oxide film doped with at least one of boron and phosphorus.

In Embodiment 5, all the hinge upper corner portions and hinge lower corner portions of the diaphragm 54 are rounded and formed to have an obtuse angle, but alternatively, only a specific hinge upper corner portion and a specific hinge lower corner portion of the diaphragm 54 may be rounded and formed to have an obtuse angle.

### Embodiment 6

A MEMS diaphragm structure having a hinge and a method for forming the same according to Embodiment 6 of the present invention will be described below with reference to the drawings.

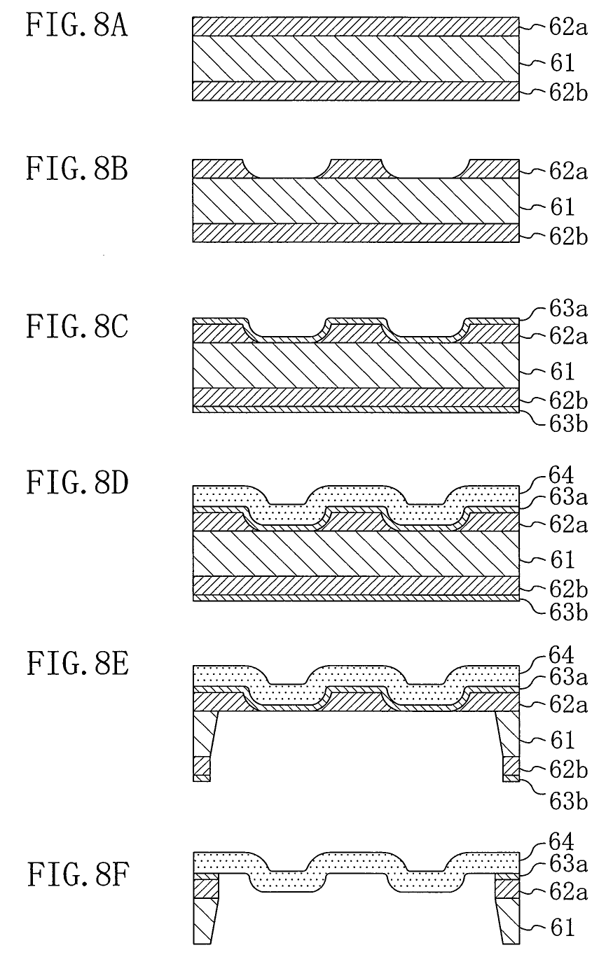

FIGS. 8A through 8F are cross-sectional views illustrating respective steps of the method for forming the diaphragm structure of Embodiment 6.

First, as illustrated with FIG. 8A, a first film 62a is formed on an upper surface of a silicon substrate 61. Here, the first film 62a desirably has a thickness of greater than or equal to about 100 nm, because the thickness of the first film 62a is a parameter which determines the height of a hinge structure of a diaphragm which is to be finally formed. Moreover, since the first film 62a is finally removed by etching, the first film 62a is desirably a silicon oxide film. A silicon oxide film can be formed by thermal oxidation, low pressure CVD, plasma CVD, or the like. In the case of using thermal oxidation or low pressure CVD, a silicon oxide film is formed not only on a silicon substrate upper surface but also on a silicon substrate reverse surface. Since low pressure CVD, for example, is used in the present embodiment to form the first film 62a of the silicon oxide film, a first film 62b of a silicon oxide film is also formed on a reverse surface of the silicon substrate 61.

Then, as illustrated with FIG. 8B, the first film 62a formed on the upper surface of the silicon substrate 61 is divided into a plurality of pieces by, for example, lithography and etching. Specifically, a photoresist is applied on the first film 62a and then exposed to light and developed for patterning to form a resist pattern. By using the resist pattern as a mask, the first film 62a is isotropically etched by wet etching. Then, the resist pattern is removed by, for example, oxygen ashing and cleaning with a sulfuric acid hydrogen peroxide solution. In this way, the first film 62a is divided into the plurality of pieces.

It is to be noted that in the present embodiment, if a silicon oxide film is used as the first film 62a, a hydrofluoric acid aqueous solution can be used as an etchant. Moreover, unlike in the case of dry etching, wet etching enables isotropic etching, and thus the first film 62a is etched also in a lateral direction (horizontal direction). Therefore, it is necessary to take an increase in etching amount in the lateral direction into consideration for determining the size of the resist pattern, that is, the mask size.

Then, as illustrated with FIG. 8C, on the upper surface of the silicon substrate 61, a second film 63a is formed to cover the patterned first film 62a. Since in the present embodiment, the second film 63a is also finally removed by etching as the first films 62a and 62b, a material film composed of the same types of elemental components as those of the first films 62a and 62b, for example, a silicon oxide film, is used as the second film 63a. Moreover, since in the present embodiment, low pressure CVD, for example, is used to form the second film 63a of the silicon oxide film, a second film 63b of a silicon oxide film is also formed on the first film 62b on a substrate reverse surface side.

It is to be noted that in the present embodiment, the shape of the second film 63a which has been formed (that is, of the second film 63a covering depressions and projections (hinge pattern) formed on the substrate upper surface by the patterned first film 62a) determines the shape of the hinge structure of the diaphragm which is to be finally formed. Therefore, it is most desirable that low pressure CVD which is excellent in coverage characteristic and thus capable of forming a film to have the same thickness on pattern side walls and flat portions is used as a method for forming the second film 63a.

Then, as illustrated with FIG. 8D, on the second film 63a, a diaphragm 64 is formed. Here, since the diaphragm 64 is formed over the hinge pattern covered with the second film 63a, the diaphragm 64 has bends. That is, the diaphragm 64 has high-level-side flat portions over the pieces of the patterned first film 62a, low-level-side flat portions between the pieces of the patterned first film 62a, and connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. As the diaphragm 64, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 64.

Then, as illustrated with FIG. 8E, each of the silicon substrate 61, the first film 62b, and the second film 63b is partially removed. Specifically, a photoresist is applied on the second film 63b on the reverse surface side of the silicon substrate 61 and then exposed to light and developed to form a resist pattern (not shown). Then, the resist pattern is used as a mask to sequentially pattern the second film 63b and the first film 62b on the substrate reverse surface side. Then, by using the patterned second film 63b and first film 62b on the substrate reverse surface side as a mask, a predetermined portion of the silicon substrate 61 is removed by etching from the reverse surface side to form a through hole in the silicon substrate 61. To etch the silicon substrate 61, dry etching or alkaline wet etching can be used. In the case of using alkaline wet etching, a silicon substrate of the (100) plane direction is used as the silicon substrate 61, and the silicon substrate 61 is immersed in an alkaline aqueous solution which is heated to a temperature of about 70-90° C. and has a concentration of 3-30 mass % of KOH, TMAH, or the like to perform anisotropic silicon wet etching on the substrate, with the (111) plane direction of the silicon being left on an etched surface. Alternatively, in the case of using dry etching, the selectivity to the second film 63b and the first film 62b which are to be used as a mask is not high (for example, the selectivity to a silicon oxide film can be increased only to about 100), but it is possible to perform etching in a direction vertical to the silicon substrate 61. By contrast, in the above-mentioned case of using wet etching, the selectivity to the second film 63b and the first film 62b which are to be used as a mask can be increased (for example, the selectivity to a silicon oxide film can be increased to about several 1000), but when the silicon substrate 61 is etched, the etched surface (pattern side wall surface) may have inclination (an inclination angle of about 54-56°). As mentioned above, since the case of using dry etching to etch the silicon substrate 61 and the case of using alkaline wet etching to etch the silicon substrate 61 show differences in etching characteristics, an optimal etching method is selected in consideration of these characteristics.

Lastly, as illustrated with FIG. 8F, the first film 62a and the second film 63a in a region exposed in the through hole of the silicon substrate 61 are removed by etching. In this way, the diaphragm (diaphragm having a hinge structure) 64 both ends of which are supported by the silicon substrate 61 and a center portion of which is in the air is formed on a substrate upper surface side. Here, in the case of using silicon oxide films as the first film 62a and the second film 63a, wet etching using a hydrofluoric acid aqueous solution as an etchant can easily remove the first film 62a and the second film 63a.

According to Embodiment 6 described above, the second film 63a and the diaphragm 64 are sequentially formed to cover the depressions and projections (the hinge pattern) formed on the substrate upper surface by the patterned first film 62a. Therefore, the hinge upper corner portions of the diaphragm 64 can be formed to have a much greater curvature (amount of rounding) than upper corner portions of the second film 63a lying thereunder. That is, since the diaphragm 64 is formed on the second film 63a after upper corner portions of the hinge pattern are rounded by the second film 63a, the hinge upper corner portions of the diaphragm 64 can be certainly rounded. Moreover, by the thickness control of the second film 63a, the round shape (amount of rounding) of the hinge upper corner portions of the diaphragm 64 can be easily controlled.

According to Embodiment 6, since grooves serving as the hinge pattern are formed by isotropically etching the first film 62a by wet etching, the side walls of the hinge pattern can be rounded. Therefore, the hinge upper corner portions and the hinge lower corner portions of the diaphragm 64 which is formed over the hinge pattern can be rounded and have an obtuse angle, and the connection portions of the diaphragm 64 located over the side walls of the hinge pattern can be rounded. That is, the hinge upper corner portions and hinge lower corner portions of the diaphragm 64 can be easily rounded and formed to have an obtuse angle. Moreover, by controlling etching conditions, the bending angle and the amount of rounding of the hinge upper corner portions and the hinge lower corner portions of the diaphragm 64 can be easily controlled.

Moreover, according to Embodiment 6, since the hinge upper corner portions and the hinge lower corner portions of the diaphragm 64 are rounded and formed to have an obtuse angle, the stress concentration on the hinge upper corner portions and the hinge lower corner portions can be dispersed, which makes it possible to improve the resistance of the diaphragm 64 against film breakage.

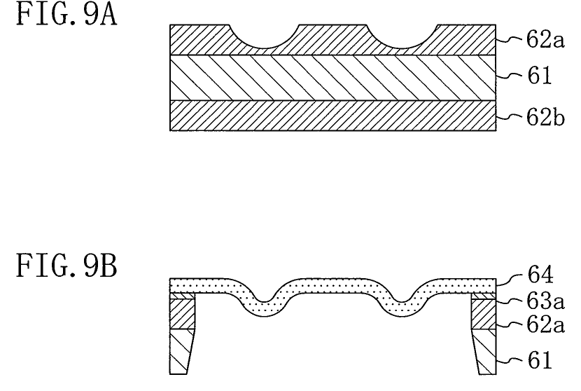

In Embodiment 6, a predetermined portion of the first film 62a is removed by etching to expose the silicon substrate 61 in the step illustrated with FIG. 8B. However, alternatively, the removal of the first film 62a by etching may be stopped before the silicon substrate 61 is exposed as illustrated with FIG. 9A. In this way, lower base portions of the hinge pattern are rounded. Therefore, the entire hinge structure including not only the hinge upper corner portions, the hinge lower corner portions, and connection portions of the diaphragm 64, but also the lower base portions of the diaphragm 64 can be rounded finally as illustrated with FIG. 9B. Here, the amount of rounding of the hinge structure can be controlled by the thickness of the first film 62a and the etching amount of the first film 62a.

In Embodiment 6, all the hinge upper corner portions and hinge lower corner portions of the diaphragm 64 are rounded and formed to have an obtuse angle, but alternatively, only a specific hinge upper corner portion and a specific hinge lower corner portion of the diaphragm 64 may be rounded and formed to have an obtuse angle.

### Embodiment 7

A MEMS diaphragm structure having a hinge and a method for forming the same according to Embodiment 7 of the present invention will be described below with reference to the drawings.

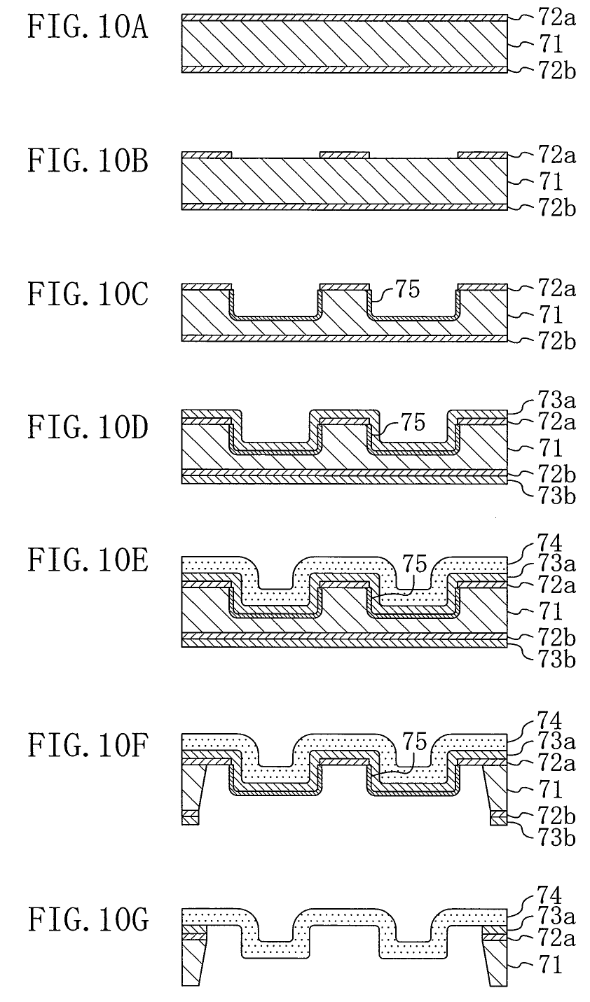

FIGS. 10A through 10G are cross-sectional views illustrating respective steps of the method for forming the diaphragm structure of Embodiment 7.

First, as illustrated with FIG. 10A, a first film 72a is formed on an upper surface of a silicon substrate 71. Here, since the first film 72a is finally removed by etching, the first film 72a is desirably a silicon oxide film. A silicon oxide film can be formed by thermal oxidation, low pressure CVD, plasma CVD, or the like. In the case of using thermal oxidation or low pressure CVD, a silicon oxide film is formed not only on a silicon substrate upper surface but also on a silicon substrate reverse surface. Since low pressure CVD, for example, is used in the present embodiment to form the first film 72a of the silicon oxide film, a first film 72b of a silicon oxide film is also formed on a reverse surface of the silicon substrate 71.

Then, as illustrated with FIG. 10B, the first film 72a formed on the upper surface of the silicon substrate 71 is divided into a plurality of pieces by, for example, lithography and etching. Specifically, a photoresist is applied on the first film 72a and then exposed to light and developed for patterning to form a resist pattern. By using the resist pattern as a mask, the first film 72a is vertically etched by dry etching. Then, the resist pattern is removed by, for example, oxygen ashing and cleaning with a sulfuric acid hydrogen peroxide solution. In this way, the first film 72a is divided into the plurality of pieces.

Then, as illustrated with FIG. 10C, by using the patterned first film 72a as a mask, the silicon substrate 71 is vertically etched by, for example, dry etching to remove the silicon substrate 71 by a predetermined depth. Depressions and projections formed by etching the silicon substrate 71 serve as a hinge pattern. Then, the silicon substrate 71 is subjected to thermal oxidation to form a silicon oxide film 75 on exposed portions of the silicon substrate 71. Here, since the etching depth of the silicon substrate 71 is a parameter which determines the height of a hinge structure of the diaphragm which is to be finally formed, the silicon substrate 71 is removed by etching by a desired depth according to the height of a hinge structure which is to be formed. For dry etching of the silicon substrate 71, a gas such as HBr or SF₆, that is, a gas which generates a halogen-based etching species is used. Moreover, in consideration of the selectivity to the first film 72a which is to be used as a mask for dry etching performed by such a gas, the thickness of the first film 72a is determined. As the first film 72a, a silicon oxide film can be used, but if this does not ensure a sufficient selectivity, a single-layer film of a silicon nitride film or a multi-layer film composed of a silicon oxide film and a silicon nitride film may be used as the first film 72a. It is to be noted that, to certainly perform thermal oxidation of the silicon substrate 71, pyrogenic oxidation is performed at a high temperature of 900° C. or higher, for example, and the heat treatment period is set such that the silicon oxide film 75 is formed to have a thickness of greater than or equal to 100 nm. In the present embodiment, the amount of rounding of upper corner portions and lower corner portions of the hinge pattern can be controlled by the thickness of the silicon oxide film 75.

Then, as illustrated with FIG. 10D, on the silicon oxide film 75 and the first film 72a on the patterned silicon substrate 71, a second film 73a is formed. Since in the present embodiment, the second film 73a is also finally removed by etching as the first films 72a and 72b, a material film composed of the same types of elemental components as those of the first films 72a and 72b, for example, a silicon oxide film, is used as the second film 73a. Moreover, since in the present embodiment, low pressure CVD, for example, is used to form the second film 73a of the silicon oxide film, a second film 73b of a silicon oxide film is also formed on the first film 72b on a substrate reverse surface side.

It is to be noted that in the present embodiment, the shape of the second film 73a which has been formed (that is, of the second film 73a covering the depressions and projections (the hinge pattern) formed on the substrate upper surface by patterning) determines the shape of the hinge structure of the diaphragm which is to be finally formed. Therefore, it is most desirable that low pressure CVD which is excellent in coverage characteristic and thus capable of forming a film to have the same thickness on pattern side walls and on flat portions is used as a method for forming the second film 73a.

Then, as illustrated with FIG. 10E, on the second film 73a, a diaphragm 74 is formed. Here, since the diaphragm 74 is formed over the hinge pattern covered with the second film 73a, the diaphragm 74 has bends. That is, the diaphragm 74 has high-level-side flat portions over substrate projections, low-level-side flat portions over bottom surfaces of substrate depressions, connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. As the diaphragm 74, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 74.

Then, as illustrated with FIG. 10F, each of the silicon substrate 71, the first film 72b, and the second film 73b is partially removed. Specifically, a photoresist is applied on the second film 73b on the reverse surface side of the silicon substrate 71 and then exposed to light and developed to form a resist pattern (not shown). Then, the resist pattern is used as a mask to sequentially pattern the second film 73b and the first film 72b on the substrate reverse surface side. Then, by using the patterned second film 73b and first film 72b on the substrate reverse surface side as a mask, a predetermined portion of the silicon substrate 71 is removed by etching from the reverse surface side to form a through hole in the silicon substrate 71. To etch the silicon substrate 71, dry etching or alkaline wet etching can be used. In the case of using alkaline wet etching, a silicon substrate of the (100) plane direction is used as the silicon substrate 71, and the silicon substrate 71 is immersed in an alkaline aqueous solution which is heated to a temperature of about 70-90° C. and has a concentration of 3-30 mass % of KOH, TMAH, or the like to perform anisotropic silicon wet etching on the substrate, with the (111) plane direction of the silicon being left on an etched surface. Alternatively, in the case of using dry etching, the selectivity to the second film 73b and the first film 72b which are to be used as a mask is not high (for example, the selectivity to a silicon oxide film can be increased only to about 100), but it is possible to perform etching in a direction vertical to the silicon substrate 71. By contrast, in the above-mentioned case of using wet etching, the selectivity to the second film 73b and the first film 72b which are to be used as a mask can be increased (for example, the selectivity to a silicon oxide film can be increased to about several 1000), but when the silicon substrate 71 is etched, the etched surface (pattern side wall surface) may have inclination (an inclination angle of about 54-56°). As mentioned above, since the case of using dry etching to etch the silicon substrate 71 and the case of using alkaline wet etching to etch the silicon substrate 71 show differences in etching characteristics, an optimal etching method is selected in consideration of these characteristics.

Lastly, as illustrated with FIG. 10G, the first film 72a and the second film 73a in a region exposed in the through hole of the silicon substrate 71 are removed by etching. In this way, the diaphragm (diaphragm having a hinge structure) 74 both ends of which are supported by the silicon substrate 71 and a center portion of which is in the air is formed on a substrate upper surface side. Here, in the case of using silicon oxide films as the first film 72a and the second film 73a, wet etching using a hydrofluoric acid aqueous solution as an etchant can easily remove the first film 72a and the second film 73a.

According to Embodiment 7 described above, the second film 73a and the diaphragm 74 are sequentially formed to cover the depressions and projections (the hinge pattern) formed on the substrate upper surface by patterning. Therefore, the hinge upper corner portions of the diaphragm 74 can be formed to have a much greater curvature (amount of rounding) than upper corner portions of the second film 73a lying thereunder. That is, since the diaphragm 74 is formed on the second film 73a after the upper corner portions of the hinge pattern are rounded by the second film 73a, the hinge upper corner portions of the diaphragm 74 can be certainly rounded. Moreover, by the thickness control of the second film 73a, the round shape (amount of rounding) of the hinge upper corner portions of the diaphragm 74 can be easily controlled.

Moreover, according to Embodiment 7, since the silicon oxide film 75 is formed by thermal oxidation on the side walls of the depressions and projections (the hinge pattern) formed on the silicon substrate 71 by etching, both the upper corner portions and the lower corner portions of the hinge pattern can be rounded. Thus, the hinge upper corner portions and the hinge lower corner portions of the diaphragm 74 formed over the hinge pattern can also be rounded. Moreover, depending on etching conditions of the silicon substrate 71, the hinge pattern side walls can be formed to have inclination, and thus the hinge upper corner portions and the hinge lower corner portions of the diaphragm 74 can be formed to have an obtuse angle. That is, the hinge upper corner portions and the hinge lower corner portions of the diaphragm 74 can be easily rounded and formed to have an obtuse angle. Moreover, it is possible to easily control the round shape (amount of rounding) of the hinge upper corner portions and the hinge lower corner portions of the diaphragm 74 by the amount of thermally oxidized silicon substrate 71.

Moreover, according to Embodiment 7, since the hinge upper corner portions and the hinge lower corner portions of the diaphragm 74 are rounded, the stress concentration on the hinge upper corner portions and the hinge lower corner portions can be dispersed, which makes it possible to improve the resistance of the diaphragm 74 against film breakage.

It is to be noted that in Embodiment 7, to certainly perform thermal oxidation of the silicon substrate, the temperature for thermal oxidation is preferably 900° C. or higher.

In Embodiment 7, all the hinge upper corner portions and hinge lower corner portions of the diaphragm 74 are rounded, but alternatively, only a specific hinge upper corner portion and a specific hinge lower corner portion of the diaphragm 74 may be rounded.

### Embodiment 8

A MEMS diaphragm structure having a hinge and a method for forming the same according to Embodiment 8 of the present invention will be described below with reference to the drawings.

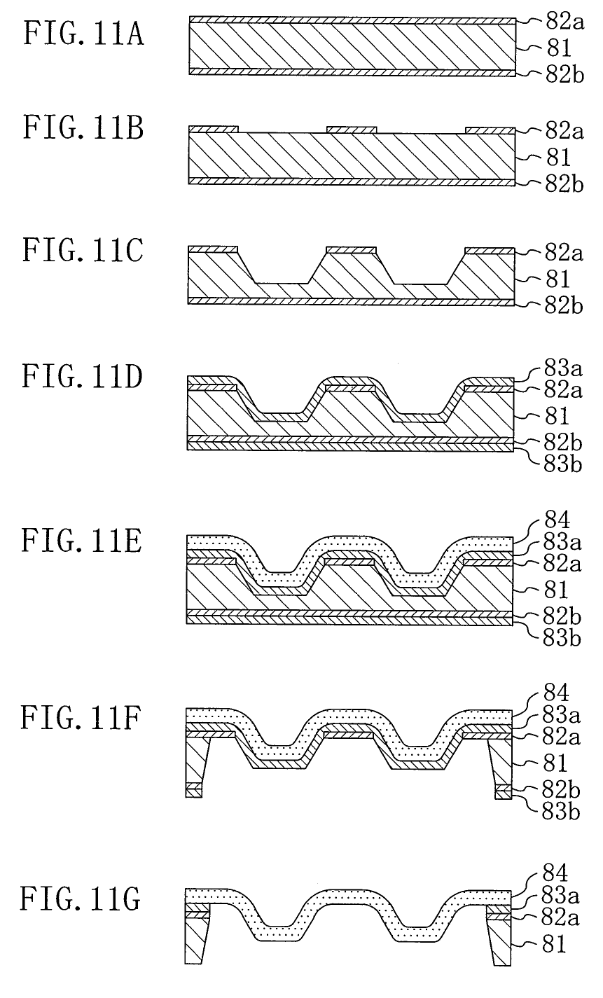

FIGS. 11A through 11G are cross-sectional views illustrating respective steps of the method for forming the diaphragm structure of Embodiment 8.

First, as illustrated with FIG. 11A, a first film 82a is formed on an upper surface of a silicon substrate 81. Here, as a silicon substrate 81, a silicon substrate whose (100) plane direction is exposed is used. Moreover, since the first film 82a is finally removed by etching, the first film 82a is desirably a silicon oxide film. A silicon oxide film can be formed by thermal oxidation, low pressure CVD, plasma CVD, or the like. In the case of using thermal oxidation or low pressure CVD, a silicon oxide film is formed not only on a silicon substrate upper surface but also on a silicon substrate reverse surface. Since low pressure CVD, for example, is used in the present embodiment to form the first film 82a of the silicon oxide film, a first film 82b of a silicon oxide film is also formed on a reverse surface of the silicon substrate 81.

Then, as illustrated with FIG. 11B, the first film 82a formed on the upper surface of the silicon substrate 81 is divided into a plurality of pieces by, for example, lithography and etching. Specifically, a photoresist is applied on the first film 82a and then exposed to light and developed for patterning to form a resist pattern. By using the resist pattern as a mask, the first film 82a is vertically etched by dry etching. Then, the resist pattern is removed by, for example, oxygen ashing and cleaning with a sulfuric acid hydrogen peroxide solution. In this way, the first film 82a is divided into the plurality of pieces.

Then, as illustrated with FIG. 11C, by using the patterned first film 82a as a mask, the silicon substrate 81 is etched by, for example, wet etching such that the silicon substrate 81 is removed by a predetermined depth and etched pattern side walls have inclination (inclination gentler than the perpendicular). Depressions and projections formed by etching the silicon substrate 81 serve as a hinge pattern. Here, since the etching depth of the silicon substrate 81 is a parameter which determines the height of a hinge structure of the diaphragm which is to be finally formed, the silicon substrate 81 is removed by etching by a desired depth according to the height of a hinge structure which is to be formed. For wet etching of the silicon substrate 81, an alkaline aqueous solution which is heated to a temperature of about 70-90° C. and has a concentration of 3-30 mass % of KOH, TMAH, or the like is used. Moreover, in consideration of the selectivity to the first film 82a which is to be used as a mask for wet etching performed by using such an etching solution, the thickness of the first film 82a is determined. As the first film 82a, a silicon oxide film can be used, but if this does not ensure a sufficient selectivity, a single-layer film of a silicon nitride film or a multi-layer film composed of a silicon oxide film and a silicon nitride film may be used as the first film 82a. As in the present embodiment, if alkaline wet etching is performed on the silicon substrate 81 whose (100) plane direction is exposed, it is possible to perform anisotropic silicon wet etching on the substrate, with the (111) plane direction of the silicon being left on the etched surface. In the present embodiment, the bending angle of the upper corner portions and the lower corner portions of the hinge pattern can be controlled by the wet etching conditions.

Then, as illustrated with FIG. 11D, on the patterned silicon substrate 81 and the first film 82a, a second film 83a is formed. Since in the present embodiment, the second film 83a is also finally removed by etching as the first films 82a and 82b, a material film composed of the same types of elemental components as those of the first films 82a and 82b, for example, a silicon oxide film, is used as the second film 83a. Moreover, since in the present embodiment, low pressure CVD, for example, is used to form the second film 83a of the silicon oxide film, a second film 83b of a silicon oxide film is also formed on the first film 82b on a substrate reverse surface side.

It is to be noted that in the present embodiment, the shape of the second film 83a which has been formed (that is, of the second film 83a covering the depressions and projections (the hinge pattern) formed on the substrate upper surface by patterning) determines the shape of the hinge structure of the diaphragm which is to be finally formed. Therefore, it is most desirable that low pressure CVD which is excellent in coverage characteristic and thus capable of forming a film to have the same thickness on pattern side walls and flat portions is used as a method for forming the second film 83a.

Then, as illustrated with FIG. 11E, on the second film 83a, a diaphragm 84 is formed. Here, since the diaphragm 84 is formed over the hinge pattern covered with the second film 83a, the diaphragm 84 has bends. That is, the diaphragm 84 has high-level-side flat portions over substrate projections, low-level-side flat portions over bottom surfaces of substrate depressions, connection portions connecting the high-level-side flat portions and the low-level-side flat portions, wherein between the high-level-side flat portions and connection portions, there are hinge upper corner portions, and between the low-level-side flat portions and connection portions, there are hinge lower corner portions. In the present embodiment, the connection portions are provided in an oblique direction to the high-level-side flat portions and the low-level-side flat portions. As the diaphragm 84, a single-layer film of a polysilicon film, a single-layer film of a silicon nitride film, a multi-layer film composed of a polysilicon film and a silicon nitride film, a multi-layer film in which a silicon oxide film is sandwiched between at least either of polysilicon films and silicon nitride films (for example, a multi-layer film having a four-layer structure composed of a silicon nitride film, a silicon oxide film, a silicon nitride film, and a polysilicon film), or the like is used according to applications. Moreover, it is most desirable that low pressure CVD which is excellent in coverage characteristic and thus capable of forming a film to have the same thickness over the pattern side walls and flat portions is used as a method for forming the diaphragm 84.

Then, as illustrated with FIG. 11F, each of the silicon substrate 81, the first film 82b, and the second film 83b is partially removed. Specifically, a photoresist is applied on the second film 83b on the reverse surface side of the silicon substrate 81 and then exposed to light and developed to form a resist pattern (not shown). Then, the resist pattern is used as a mask to sequentially pattern the second film 83b and the first film 82b on the substrate reverse surface side. Then, by using the patterned second film 83b and first film 82b on the substrate reverse surface side as a mask, a predetermined portion of the silicon substrate 81 is removed by etching from the reverse surface side to form a through hole in the silicon substrate 81. To etch the silicon substrate 81, dry etching or alkaline wet etching can be used. In the case of using a silicon substrate of the (100) plane direction as the silicon substrate 81 and using alkaline wet etching, the silicon substrate 81 is immersed in an alkaline aqueous solution which is heated to a temperature of about 70-90° C. and has a concentration of 3-30 mass % of KOH, TMAH, or the like to perform anisotropic silicon wet etching on the substrate, with the (111) plane direction of the silicon being left on an etched surface. Alternatively, in the case of using dry etching, the selectivity to the second film 83b and the first film 82b which are to be used as a mask is not high (for example, the selectivity to a silicon oxide film can be increased only to about 100), but it is possible to perform etching in a direction vertical to the silicon substrate 81. By contrast, in the above-mentioned case of using wet etching, the selectivity to the second film 83b and the first film 82b which are to be used as a mask can be increased (for example, the selectivity to a silicon oxide film can be increased to about several 1000), but when the silicon substrate 81 is etched, the etched surface (pattern side wall surface) may have inclination (an inclination angle of about 54-56°). As mentioned above, since the case of using dry etching to etch the silicon substrate 81 and the case of using alkaline wet etching to etch the silicon substrate 81 show differences in etching characteristics, an optimal etching method is selected in consideration of these characteristics.

Lastly, as illustrated with FIG. 11G, the first film 82a and the second film 83a in a region exposed in the through hole of the silicon substrate 81 are removed by etching. In this way, the diaphragm (diaphragm having a hinge structure) 84 both ends of which are supported by the silicon substrate 81 and a center portion of which is in the air is formed on a substrate upper surface side. Here, in the case of using silicon oxide films as the first film 82a and the second film 83a, wet etching using a hydrofluoric acid aqueous solution as an etchant can easily remove the first film 82a and the second film 83a.

According to Embodiment 8 described above, the second film 83a and the diaphragm 84 are sequentially formed to cover the depressions and projections (the hinge pattern) formed on the substrate upper surface by patterning. Therefore, the hinge upper corner portions of the diaphragm 84 can be formed to have a much greater curvature (amount of rounding) than upper corner portions of the second film 83a lying thereunder. That is, since the diaphragm 84 is formed on the second film 83a after upper corner portions of the hinge pattern are rounded by the second film 83a, the hinge upper corner portions of the diaphragm 84 can be certainly rounded. Moreover, by the thickness control of the second film 83a, the round shape (amount of rounding) of the hinge upper corner portions of the diaphragm 84 can be easily controlled.

Moreover, according to Embodiment 8, since the side walls of the depressions and projections (the hinge pattern) formed on the silicon substrate 81 by etching have inclination (inclination gentler than the perpendicular), the hinge upper corner portions and the hinge lower corner portions of the diaphragm 84 which is formed over the hinge pattern can have an obtuse angle. That is, the hinge upper corner portions and the hinge lower corner portions of the diaphragm 84 can be easily formed to have an obtuse angle. Moreover, by controlling the etching conditions, the bending angle of the hinge upper corner portions and the hinge lower corner portions of the diaphragm 84 can be easily controlled.

Moreover, according to Embodiment 8, since the hinge upper corner portions and the hinge lower corner portions of the diaphragm 84 are rounded and formed to have an obtuse angle, the stress concentration on the hinge upper corner portions and the hinge lower corner portions can be dispersed, which makes it possible to improve the resistance of the diaphragm 84 against film breakage.

It is to be noted that in Embodiment 8, to certainly form the hinge pattern side walls to have inclination, it is preferable that the silicon substrate 81 is a silicon substrate whose (100) plane direction is exposed, and in silicon substrate etching, anisotropic etching is performed by wet etching using an alkaline solution.

In Embodiment 8, all the hinge upper corner portions and hinge lower corner portions of the diaphragm 84 are rounded and formed to have an obtuse angle, but alternatively, only a specific hinge upper corner portion and a specific hinge lower corner portion of the diaphragm 84 may be rounded and formed to have an obtuse angle.

Moreover, the embodiments of the present invention described above can be combined with each other. For example, Embodiment 4 can be used with each of Embodiment 2, Embodiment 3, Embodiment 5, Embodiment 6, and Embodiment 7. Embodiment 8 can be used with each of Embodiment 2, Embodiment 3, Embodiment 4, and Embodiment 5.

Moreover, in embodiments of the present invention, respectively different positions of the hinge corner portions are formed to have an obtuse angle or rounded, or respectively different positions of the hinge corner portions are reinforced. Therefore, according to stress concentration position of the hinge structure in the course of formation process of the diaphragm or in the actual use of diaphragm as a sensor, an appropriate embodiment may be selected to disperse or ease the stress on the position or to reinforce the position.

Moreover, in a condenser including a pair of electrodes facing each other, if one of the pair of electrodes has a diaphragm structure or is formed on a diaphragm structure according to each of the embodiments of the present invention, the resistance of the diaphragm against film breakage can be improved, so that it is possible to realize a condenser having high reliability.

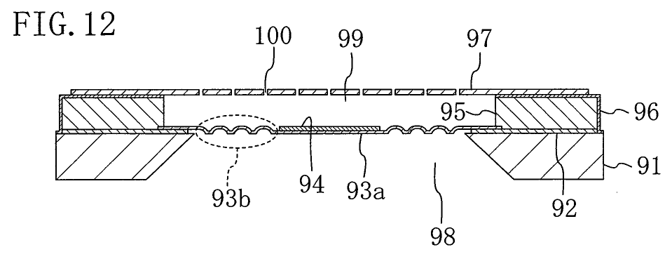

Moreover, in an electret condenser microphone (ECM) including a pair of electrodes facing each other and an electret disposed between the pair of electrodes, if one of the pair of electrodes has a diaphragm structure or is formed on a diaphragm structure according to each of the embodiments of the present invention, the resistance of the diaphragm against film breakage can be improved, so that it is possible to realize an electret condenser microphone having high reliability. FIG. 12 is a cross-sectional view showing an example of an electret condenser microphone to which a diaphragm structure (diaphragm having a hinge structure) according to each of the embodiments of the present invention is applied. As shown in FIG. 12, provided on a silicon substrate 91 is an underlayer protective film 92 formed by, for example, a silicon oxide film. In the center (membrane region) of the silicon substrate 91 and the underlayer protective film 92, a through hole 98 is formed. On the underlayer protective film 92, a diaphragm (diaphragm electrode) 93 is formed to cover the membrane region. Moreover, over the diaphragm electrode 93, a fixing film (fixing film electrode) 97 is provided to face the diaphragm electrode 93. On the silicon substrate 91 excepting the membrane region, to keep the distance between the diaphragm electrode 93 and the fixing film electrode 97 constant, an insulating film 95 and its protection film (upper surface protection film) 96 are provided, and an air gap 99 is provided between the diaphragm electrode 93 and the fixing film electrode 97. The fixing film electrode 97 has a plurality of acoustic holes 100 opened to the air gap 99. Moreover, on a portion 93a of the diaphragm electrode 93 which is located close to the center of the membrane region, an electret film 94 is formed. Furthermore, a portion 93b of the diaphragm electrode 93 which is located on the periphery of the membrane region has a diaphragm structure (diaphragm having a hinge structure) according to each of the embodiments of the present invention. It is to be noted that the diaphragm electrode 93 and the fixing film electrode 97 may be provided upside down. Moreover, as long as the electret film 94 is disposed between the diaphragm electrode 93 and the fixing film electrode 97, the electret film 94 may not be disposed directly on the diaphragm electrode 93.

### INDUSTRIAL APPLICABILITY

As described above, the diaphragm structure and the method for forming the same according to the present invention are applicable to, for example, an ECM which has a small size and high performance and is excellent in productivity.

1. A diaphragm structure comprising a diaphragm formed using MEMS technology, wherein
the diaphragm has a hinge structure, and
at least one of a hinge upper corner portion and a hinge lower corner portion of the diaphragm is bent at an angle greater than 90°.

2. The diaphragm structure of claim 1, wherein
the diaphragm has a high-level-side flat portion, a low-level-side flat portion, and a connection portion connecting the high-level-side flat portion and the low-level-side flat portion, and
the connection portion is provided in an oblique direction to the high-level-side flat portion and the low-level-side flat portion.

3. A diaphragm structure comprising a diaphragm formed using MEMS technology, wherein
the diaphragm has a hinge structure, and
at least one of a hinge upper corner portion and a hinge lower corner portion of the diaphragm is rounded.

4. The diaphragm structure of claim 3, wherein the other portions of the diaphragm than the hinge upper corner portion and the hinge lower corner portion are also rounded.

5. A diaphragm structure comprising a diaphragm formed using MEMS technology, wherein
the diaphragm has a hinge structure, and
at least one of a hinge upper corner portion and a hinge lower corner portion of the diaphragm is reinforced by having a film thickness greater than that of the other portions of the diaphragm.

6. The diaphragm structure of claim 5, wherein
the diaphragm has a high-level-side flat portion, a low-level-side flat portion, and a connection portion connecting the high-level-side flat portion and the low-level-side flat portion, and
the connection portion has a sidewall spacer structure.

7. A condenser comprising a pair of electrodes facing each other, wherein one of the pair of electrodes has the diaphragm structure according to claim 1 or is formed on the diaphragm structure according to claim 1.

8. An electret condenser microphone comprising a pair of electrodes facing each other and an electret disposed between the pair of electrodes, wherein
one of the pair of electrodes has the diaphragm structure according to claim 1 or is formed on the diaphragm structure according to claim 1.

9. A method for forming a diaphragm structure including a diaphragm formed using MEMS technology, the method comprising the steps of:
(a) forming a first film on a substrate;
(b) patterning the first film;
(c) forming a second film over the substrate to cover the patterned first film;
(d) forming a diaphragm on the second film;
(e) forming a through hole in the substrate from a side of the substrate where the diaphragm is not formed; and
(f) removing the first film and the second film in a region exposed in the through hole.

10. The method of claim 9, wherein the first film and the second film are formed of the same material.

11. The method of claim 9, wherein
the first film and the second film are also formed on a reverse surface of the substrate where the diaphragm is not to be formed, and
step (e) includes patterning the first film and the second film formed on the reverse surface and etching the substrate using the patterned first and second films on the reverse surface as a mask.

12. The method of claim 9, wherein
the first film and the second film are silicon oxide films, and
in step (f), the first film and the second film are removed by etching with hydrofluoric acid.

13. The method of claim 9, wherein the diaphragm is a single-layer film of a polysilicon film, a single-layer film of a silicon nitride film, a multi-layer film composed of a polysilicon film and a silicon nitride film, or a multi-layer film in which a silicon oxide film is sandwiched between at least either of polysilicon films and silicon nitride films.

14. The method of claim 9, comprising between steps (b) and (c) the step of forming a sidewall spacer on a side wall of the patterned first film.

15. The method of claim 9, comprising between steps (c) and (d) the step of forming a sidewall spacer over a side wall of the patterned first film with the second film interposed therebetween.

16. The method of claim 14, wherein
the first film, the second film, and the sidewall spacer are formed of the same material, and
in step (f), the sidewall spacer is removed together with the first film and the second film.

17. The method of claim 9, comprising between steps (c) and (d) the step of forming a sidewall spacer over a side wall of the patterned first film with the second film interposed therebetween, wherein
the sidewall spacer is formed of a material different from that of the first and second films, and
in step (f), the sidewall spacer is left.

18. The method of claim 17, wherein the sidewall spacer is a silicon nitride film or a polysilicon film.

19. The method of claim 9, comprising between steps (d) and (e) the step of forming a sidewall spacer over a side wall of the patterned first film with the second film and the diaphragm interposed therebetween, wherein
the sidewall spacer is formed of a material different from that of the first and second films, and
in step (f), the sidewall spacer is left.

20. The method of claim 19, wherein the sidewall spacer is a silicon nitride film or a polysilicon film.

21. The method of claim 9, further comprising between steps (c) and (d) the step of performing a heat treatment to allow the second film to flow.

22. The method of claim 21, wherein the heat treatment is performed at a temperature of higher than or equal to 600° C.

23. The method of claim 21, wherein the second film is a silicon oxide film doped with at least one of boron or phosphorus.

24. The method of claim 9, wherein step (b) includes isotropically etching the first film by wet etching.

25. The method of claim 24, wherein in step (b), the etching is performed such that the substrate is not exposed.

26. The method of claim 9, wherein
the substrate is a silicon substrate, and
the method further includes between steps (b) and (c) the steps of removing the silicon substrate by a predetermined depth by etching using the patterned first film as a mask, and then performing a thermal oxidation on the silicon substrate.

27. The method of claim 26, wherein the thermal oxidation is performed at a temperature of higher than or equal to 900° C.

28. The method of claim 9, further comprising between steps (b) and (c) the step of etching the silicon substrate using the patterned first film as a mask such that the silicon substrate is removed by a predetermined depth and an etched pattern side wall has inclination.

29. The method of claim 28, wherein
the substrate is a silicon substrate whose (100) plane direction is exposed, and
for etching the silicon substrate, anisotropic etching is performed by wet etching using an alkaline solution.
